(19) United States
(12) Patent Application Publication
(10) Pub. No.: US 2022/0165875 A1
(43) Pub. Date: May 26, 2022

(54) NITRIDE SEMICONDUCTOR APPARATUS

(71) Applicant: ROHM Co., LTD., Kyoto (JP)

(72) Inventors: Hirotaka OTAKE, Kyoto (JP); Shinya TAKADO, Kyoto (JP)

(21) Appl. No.: 17/532,172

(22) Filed: Nov. 22, 2021

(30) Foreign Application Priority Data
Nov. 26, 2020 (JP) 2020-196157

(51) Int. Cl. H01L 29/778

(52) U.S. Cl. CPC H01L 29/7786

(57) ABSTRACT

Disclosed herein is a nitride semiconductor apparatus including an electron transit layer including a nitride semiconductor, an electron supply layer that is formed on the electron transit layer and includes a nitride semiconductor with a band gap larger than a band gap of the electron transit layer, a step layer that is formed on part of the electron supply layer and includes a nitride semiconductor with a band gap smaller than the band gap of the electron supply layer, a gate layer that is formed on part of the electron supply layer or part of the step layer and contains acceptor impurities, a gate electrode formed on the gate layer, and a source electrode and a drain electrode that are in contact with the electron supply layer. The step layer includes extension portions extending outside of the gate layer in plan view. The extension portions each include an undoped layer.

### CROSS REFERENCE TO RELATED APPLICATIONS

This application claims priority benefit of Japanese Patent Application No. JP 2020-196157 filed in the Japan Patent Office on Nov. 26, 2020. Each of the above-referenced applications is hereby incorporated herein by reference in its entirety.

### BACKGROUND

The present disclosure relates to a nitride semiconductor apparatus.

In recent years, a high electron mobility transistor (HEMT) including a nitride semiconductor as a main material of an active region is proposed, and the HEMT is increasingly applied to power devices. The nitrogen semiconductor is a semiconductor in which nitrogen is used as a group V element in a III-V semiconductor. Compared to a typical silicon carbide (SiC) power device, the power device including the nitride semiconductor is recognized as a device that has a feature of low on-resistance as in the SiC power device and that can operate at higher speed and higher frequency than the SiC power device.

A normally-off operation of cutting off the current path (channel) between the source and the drain during zero bias without application of a gate voltage is desired in the power transistor, such as HEMT, from the viewpoint of fail-safe. A nitride semiconductor apparatus that realizes a normally-off power transistor is described in Japanese Patent Laid-Open No. 2017-73506 (hereinafter, referred to as Patent Document 1).

In the nitride semiconductor apparatus described in Patent Document 1, a gallium nitride (GaN) layer, which is also called an electron transit layer, and an aluminum gallium nitride (AlGaN) layer, which is also called an electron supply layer and is laminated on the electron transit layer, form a heterojunction. A two-dimensional electron gas (2DEG) is formed as a channel on the GaN layer at a position near the heterojunction interface between the electron transit layer and the electron supply layer, and a GaN layer doped with acceptor impurities (p-type GaN layer) is provided on the electron supply layer just below the gate electrode. The channel of the electron transit layer in the region just below the gate electrode disappears due to the existence of the acceptor impurities included in the p-type GaN layer, and the normally-off operation is thus realized. An appropriate ON voltage is applied to the gate electrode to induce the channel on the electron transit layer in the region just below the gate electrode, and the source and the drain are thus conducted.

In the structure of Patent Document 1 described above, the gate electrode and the p-type GaN layer form a Schottky junction, and an energy barrier is formed in the interface of the gate electrode and the p-type GaN layer. This energy barrier and an energy barrier of the electron supply layer maintain the gate withstand voltage. However, application of a large positive bias to the gate electrode in the structure described above may increase the gate leakage current. For example, when an excessive positive bias is applied to the gate electrode due to an external factor, such as influence of parasitic inductance, holes are injected from the gate electrode to the p-type GaN layer and stored in the interface of the p-type GaN layer and the electron supply layer. The hole storage causes band bending of the electron supply layer, and the electrons move (electron leakage) from the electron transit layer to the p-type GaN layer through the electron supply layer. Such electron leakage increases the gate leakage current and reduces the gate withstand voltage.

### SUMMARY

An aspect of the present disclosure provides a nitride semiconductor apparatus including an electron transit layer including a nitride semiconductor, an electron supply layer that is formed on the electron transit layer and includes a nitride semiconductor with a band gap larger than a band gap of the electron transit layer, a step layer that is formed on part of the electron supply layer and includes a nitride semiconductor with a band gap smaller than the band gap of the electron supply layer, a gate layer that is formed on part of the electron supply layer or part of the step layer and contains acceptor impurities, a gate electrode formed on the gate layer, and a source electrode and a drain electrode that are in contact with the electron supply layer. The step layer includes extension portions extending outside of the gate layer in plan view, and the extension portions each include an undoped layer.

According to this configuration, the extension portions including the undoped layers extend outside of the gate layer in plan view. This suppresses the depletion of the two-dimensional electron gas in the region just below the extension portions and reduces the hole density in the interface between the step layer and the electron supply layer. Therefore, a rise in on-resistance can be suppressed, and the gate leakage current can be reduced to improve the gate withstand voltage in the nitride semiconductor apparatus.

According to an aspect of the nitride semiconductor apparatus of the present disclosure, the gate leakage current can be reduced to improve the gate withstand voltage.

### BRIEF DESCRIPTION OF THE DRAWINGS

FIG. 1 is a schematic cross-sectional view of an exemplary nitride semiconductor apparatus according to a first embodiment;

FIG. 2 is a partially enlarged cross-sectional view of the nitride semiconductor apparatus in FIG. 1;

FIG. 3 is a schematic cross-sectional view illustrating an exemplary manufacturing process of the nitride semiconductor apparatus in FIG. 1;

FIG. 4 is a schematic cross-sectional view illustrating a manufacturing process following FIG. 3;

FIG. 5 is a schematic cross-sectional view illustrating a manufacturing process following FIG. 4;

FIG. 6 is a schematic cross-sectional view illustrating a manufacturing process following FIG. 5;

FIG. 7 is a schematic cross-sectional view illustrating a manufacturing process following FIG. 6;

FIG. 8 is a schematic cross-sectional view illustrating a manufacturing process following FIG. 7;

FIG. 9 is a schematic cross-sectional view illustrating a manufacturing process following FIG. 8;

FIG. 10 is a schematic cross-sectional view illustrating a manufacturing process following FIG. 9;

FIG. 11 is a schematic cross-sectional view of an exemplary nitride semiconductor apparatus according to a second embodiment;

FIG. 12 is a schematic cross-sectional view illustrating an exemplary manufacturing process of the nitride semiconductor apparatus in FIG. 11;

FIG. 13 is a schematic cross-sectional view of an exemplary nitride semiconductor apparatus according to a third embodiment;

FIG. 14 is a schematic cross-sectional view of an exemplary nitride semiconductor apparatus according to a fourth embodiment;

FIG. 15 is a schematic cross-sectional view illustrating an exemplary manufacturing process of the nitride semiconductor apparatus in FIG. 14;

FIG. 16 is a schematic cross-sectional view of an exemplary nitride semiconductor apparatus according to a fifth embodiment;

FIG. 17 is a schematic cross-sectional view of an exemplary nitride semiconductor apparatus according to a sixth embodiment;

FIG. 18 is a schematic cross-sectional view illustrating an exemplary manufacturing process of the nitride semiconductor apparatus in FIG. 17;

FIG. 19 is a schematic cross-sectional view illustrating a manufacturing process following FIG. 18;

FIG. 20 is a schematic cross-sectional view illustrating a manufacturing process following FIG. 19;

FIG. 21 is a schematic cross-sectional view illustrating a manufacturing process following FIG. 20;

FIG. 22 is a schematic cross-sectional view illustrating a manufacturing process following FIG. 21;

FIG. 23 is a schematic cross-sectional view illustrating a manufacturing process following FIG. 22;

FIG. 24 is a schematic cross-sectional view illustrating a manufacturing process following FIG. 23;

FIG. 25 is a schematic cross-sectional view of an exemplary nitride semiconductor apparatus according to a seventh embodiment;

FIG. 26 is a schematic cross-sectional view illustrating an exemplary manufacturing process of the nitride semiconductor apparatus in FIG. 25;

FIG. 27 is a schematic cross-sectional view illustrating a manufacturing process following FIG. 26;

FIG. 28 is a schematic cross-sectional view illustrating a manufacturing process following FIG. 27;

FIG. 29 is a schematic cross-sectional view illustrating a manufacturing process following FIG. 28;

FIG. 30 is a schematic cross-sectional view illustrating a manufacturing process following FIG. 29;

FIG. 31 is a schematic cross-sectional view illustrating a manufacturing process following FIG. 30;

FIG. 32 is a schematic cross-sectional view illustrating a manufacturing process following FIG. 31;

FIG. 33 is a schematic cross-sectional view illustrating a manufacturing process following FIG. 32;

FIG. 34 is a schematic cross-sectional view illustrating a manufacturing process following FIG. 33;

FIG. 35 is a schematic cross-sectional view illustrating a manufacturing process following FIG. 34;

FIG. 36 is a schematic cross-sectional view of an exemplary nitride semiconductor apparatus according to an eighth embodiment;

FIG. 37 is a schematic plan view illustrating an exemplary formation pattern of the nitride semiconductor apparatus in FIG. 1;

FIG. 38 is a schematic cross-sectional view of an active region along a line F38-F38 in FIG. 37;

FIG. 39 is a schematic cross-sectional view of an inactive region along a line F39-F39 in FIG. 37;

FIG. 40 is a schematic plan view illustrating another exemplary formation pattern of the nitride semiconductor apparatus in FIG. 1; and

FIG. 41 is a schematic cross-sectional view of an inactive region along a line F41-F41 in FIG. 40.

### DETAILED DESCRIPTION OF THE PREFERRED EMBODIMENTS

Embodiments of a nitride semiconductor apparatus according to the present disclosure will now be described with reference to the attached drawings.

Note that the constituent elements in the drawings are partially enlarged for the ease of understanding and clarification in some cases, and the constituent elements may not be depicted in actual reduced scales. To facilitate the understanding, hatch lines are not illustrated in the cross-sectional views in some cases.

### First Embodiment

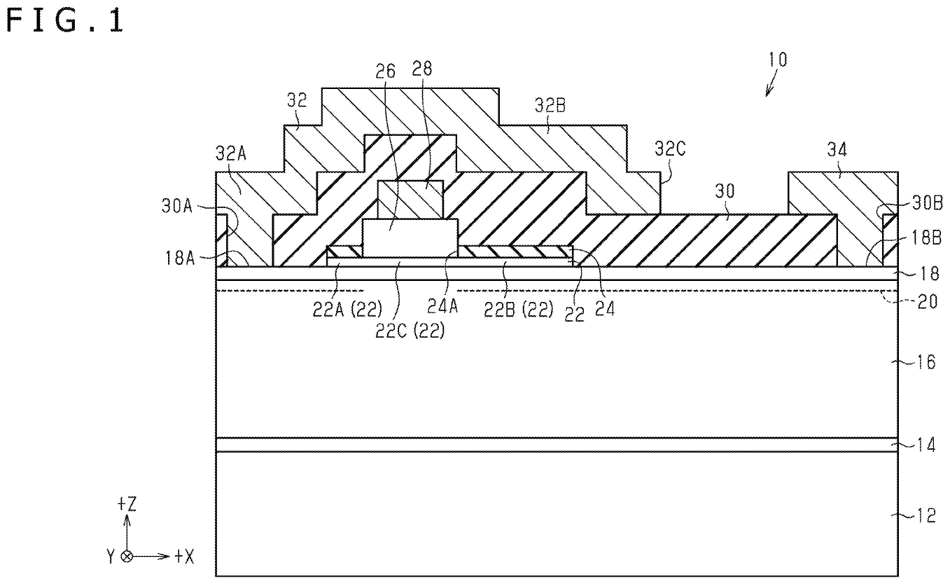

FIG. 1 is a schematic cross-sectional view of an exemplary nitride semiconductor apparatus 10 according to a first embodiment. Note that words “in plan view” used in the present disclosure denote that the nitride semiconductor apparatus 10 is viewed in a Z-axis direction of X-, Y-, Z-axes orthogonal to one another illustrated in FIG. 1. In the nitride semiconductor apparatus 10 illustrated in FIG. 1, a +Z direction represents “up,” a −Z direction represents “down,” a +X direction represents “right,” and a −X direction represents “left.” Unless otherwise stated, “in plan view” denotes that the nitride semiconductor apparatus 10 is viewed from above along the Z-axis.

The nitride semiconductor apparatus 10 is a HEMT with a nitride semiconductor. The nitride semiconductor apparatus 10 includes a substrate 12, a buffer layer 14 formed on the substrate 12, an electron transit layer 16 formed on the buffer layer 14, and an electron supply layer 18 formed on the electron transit layer 16.

The substrate 12 can be, for example, a silicon substrate. For example, the substrate 12 can be a p-type silicon substrate with electrical resistivity of equal to or greater than 0.001 Ωmm and equal to or smaller than 0.5 Ωmm (or equal to or greater than 0.01 Ωmm and equal to or smaller than 0.1 Ωmm). Instead of the silicon substrate, a sapphire substrate, a silicon carbide (SiC) substrate, a gallium nitride (GaN) substrate, or other substrates can also be used. The thickness of the substrate 12 can be, for example, equal to or greater than 200 μm and equal to or smaller than 700 μm.

The buffer layer 14 includes one or a plurality of nitride semiconductor films. For example, the buffer layer 14 may include at least one of an aluminum nitride (AlN) film, an aluminum gallium nitride (AlGaN) film, and an AlGaN composite film with different aluminum (Al) compositions (hereinafter, referred to as a “graded AlGaN layer”). For example, the buffer layer 14 may include a single film of AlN, a single film of AlGaN, a film including an AlGaN/GaN superlattice structure, a film including an AlN/AlGaN superlattice structure, or a film including an AlN/GaN superlattice structure.

In the first embodiment, the buffer layer 14 is a multi-layer buffer layer including a first buffer layer that is an AlN layer formed on the substrate 12; and a second buffer layer that is a graded AlGaN layer formed on the AlN layer. In this case, the thickness of the first buffer layer can be, for example, equal to or greater than 80 nm and equal to or smaller than 500 nm. The second buffer layer can be, for example, a graded AlGaN layer including three AlGaN layers with Al compositions of 75%, 50%, and 25% from the side closest to the first buffer layer. The thickness of the second buffer layer (total thickness of three AlGaN layers) can be, for example, equal to or greater than 300 nm and equal to or smaller than 1 μm. Note that the graded AlGaN layer can include any appropriate number of AlGaN layers. The thicknesses of the AlGaN layers in the graded AlGaN layer may be the same or may be different. Note that, to suppress the leakage current in the buffer layer 14, impurities may be introduced into part of the buffer layer 14 to make the buffer layer 14 semi-insulating except for a surface layer region. In that case, the impurities include, for example, carbon (C) or iron (Fe), and the concentration of the impurities can be, for example, equal to or greater than 4×10¹⁶ cm⁻³.

The electron transit layer 16 includes a nitride semiconductor, and the electron transit layer 16 is a GaN layer in the first embodiment. The thickness of the electron transit layer 16 can be, for example, equal to or greater than 0.5 μm and equal to or smaller than 2 μm. Note that, to suppress the leakage current in the electron transit layer 16, impurities may be introduced into part of the electron transit layer 16 to make the electron transit layer 16 semi-insulating except for the surface layer region. In that case, the impurities include, for example, C, and the concentration of the impurities can be, for example, equal to or greater than 4×10¹⁶ cm⁻³.

The electron supply layer 18 includes a nitride semiconductor with a band gap larger than the band gap of the electron transit layer 16, and the electron supply layer 18 is an AlGaN layer in the first embodiment. The higher the Al composition in the nitride semiconductor, the larger the band gap. Therefore, the band gap of the electron supply layer 18 that is an AlGaN layer is larger than the band gap of the electron transit layer 16 that is a GaN layer. For example, the electron supply layer 18 contains AlₓGa₁₋ₓN in the first embodiment, and x is preferably 0<x<0.4, more preferably, 0.1<x<0.3. The thickness of the electron supply layer 18 can be, for example, equal to or greater than 5 nm and equal to or smaller than 20 nm.

The electron transit layer 16 and the electron supply layer 18 have different lattice constants in a bulk region, and the layers form a lattice mismatch heterojunction. Due to the spontaneous polarization of the electron transit layer 16 and the electron supply layer 18 and the piezoelectric polarization caused by the compressive stress received by the heterojunction of the electron supply layer 18, the energy level of the conduction band of the electron transit layer 16 near the heterojunction interface between the electron transit layer 16 and the electron supply layer 18 is lower than the Fermi level. Therefore, a two-dimensional electron gas (2DEG) 20 is spread in the electron transit layer 16 at a position near the heterojunction interface between the electron transit layer 16 and the electron supply layer 18 (for example, at a distance of approximately several nanometers from the interface).

The nitride semiconductor apparatus 10 further includes a step layer 22 that is formed on part of the electron supply layer 18 and that includes a nitride semiconductor with a band gap smaller than the band gap of the electron supply layer 18; and a first passivation layer 24 formed on the step layer 22. The nitride semiconductor apparatus 10 also includes a gate layer 26 that is formed on part of the electron supply layer 18 or the step layer 22 and that includes a nitride semiconductor containing acceptor impurities; and a gate electrode 28 formed on the gate layer 26. In the first embodiment, the gate layer 26 is formed on part of the step layer 22. The nitride semiconductor apparatus 10 also includes a second passivation layer 30; and a source electrode 32 and a drain electrode 34 going through the second passivation layer 30 and coming into contact with the electron supply layer 18.

The second passivation layer 30 includes a source contact hole 30A and a drain contact hole 30B that expose part of the top surface of the electron supply layer 18 as a source contact 18A and a drain contact 18B, respectively, and the source electrode 32 and the drain electrode 34 are joined to the electron supply layer 18 to make an ohmic contact with the 2DEG 20 through the source contact hole 30A and the drain contact hole 30B, respectively. The source contact 18A, the step layer 22, and the drain contact 18B are lined up in the X direction when the nitride semiconductor apparatus 10 is viewed in the cross section of the ZX plane. Therefore, the source contact 18A is positioned in the −X direction with respect to the step layer 22, and the drain contact 18B is positioned in the +X direction with respect to the step layer 22. Although not illustrated, the source electrode 32 is electrically connected to the substrate 12.

The step layer 22 is formed on part of the electron supply layer 18 and includes a nitride semiconductor with a band gap smaller than the band gap of the electron supply layer 18. The step layer 22 is a GaN layer in the first embodiment. Therefore, the band gap of the step layer 22 that is a GaN layer is smaller than the band gap of the electron supply layer 18 that is an AlGaN layer. The step layer 22 is an undoped layer. The term “undoped layer” used in the present disclosure represents a layer in which impurities are intentionally not introduced. However, impurities are mixed in the step layer 22 without intention in some cases during the formation process of the nitride semiconductor apparatus 10. The step layer 22 may contain, for example, acceptor impurities at a concentration of equal to or smaller than 1×10¹⁸ cm⁻³. The step layer 22 is arranged between the source contact 18A and the drain contact 18B and separated from the source contact 18A and the drain contact 18B. The step layer 22 is arranged closer to the source contact hole 30A than to the drain contact hole 30B. The distance between the step layer 22 and the drain contact 18B in plan view can be set from the viewpoint of maintaining the withstand voltage between the gate and the drain. For example, the step layer 22 is separated by, for example, equal to or greater than 0.5 μm from the source contact 18A in plan view and is separated by, for example, equal to or greater than 3.0 μm from the drain contact 18B in plan view.

The step layer 22 includes a source-side extension portion 22A, a drain-side extension portion 22B, and a base portion 22C. In the first embodiment, the source-side extension portion 22A corresponds to a “first extension portion,” and the drain-side extension portion 22B corresponds to a “second extension portion.”

The base portion 22C is positioned between the source-side extension portion 22A and the drain-side extension portion 22B in the direction along the X-axis in FIG. 1. However, there is no physical boundary between the base portion 22C and each of the extension portions 22A and 22B. The base portion 22C is defined as a part of the step layer 22 positioned in a region just below the gate layer 26, and therefore, the width of the base portion 22C is the same as the width of the gate layer 26. Note that the “width” used in the present disclosure represents a length along the X-axis in FIG. 1 unless otherwise stated.

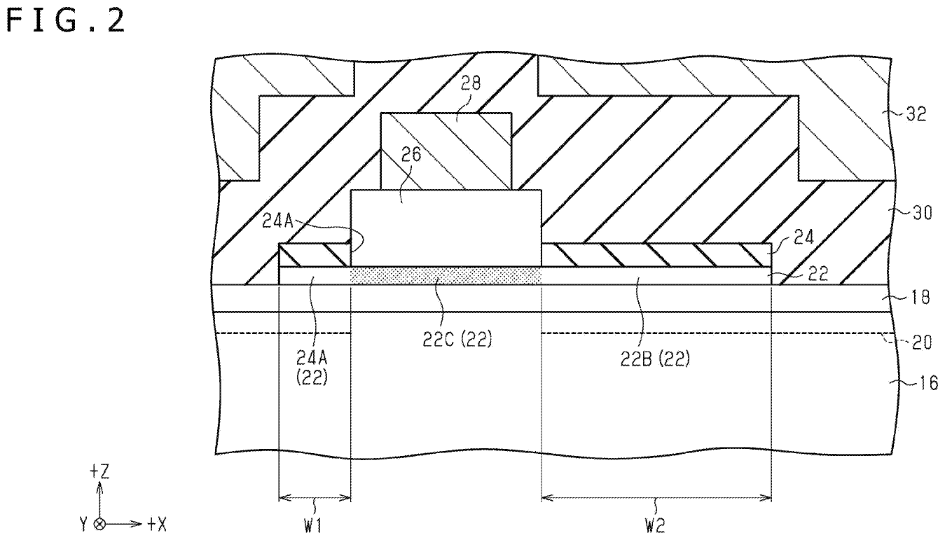

The source-side extension portion 22A is part of the step layer 22, the source-side extension portion 22A being adjacent to the base portion 22C and extending in the −X direction from the boundary with the base portion 22C toward the source contact 18A. The drain-side extension portion 22B is part of the step layer 22, the drain-side extension portion 22B being adjacent to the base portion 22C and extending in the +X direction from the boundary with the base portion 22C toward the drain contact 18B. Therefore, the source-side extension portion 22A and the drain-side extension portion 22B extend outside of the gate layer 26 in plan view. A width W2 of the drain-side extension portion 22B is the same as or larger than a width W1 of the source-side extension portion 22A (see FIG. 2 for W1 and W2).

For example, when the width W1 of the source-side extension portion 22A and the width W2 of the drain-side extension portion 22B are increased, an improvement in gate withstand voltage can be expected. However, there may be tradeoffs that (1) the leakage between the gate and the source may increase when the source-side extension portion 22A extends to near the source contact 18A and (2) an effect of extending a depletion layer from a source field plate length described later may be reduced when the drain-side extension portion 22B extends longer than the source field plate length. The tradeoffs can be taken into account to set the width of each of the extension portions 22A and 22B. For example, the width W1 of the source-side extension portion 22A is equal to or greater than 0.1 μm and equal to or smaller than 0.3 μm, and the width W2 of the drain-side extension portion 22B is equal to or greater than 0.1 μm and equal to or smaller than 0.8 μm. In the first embodiment, the width W1 of the source-side extension portion 22A is approximately 0.2 μm, and the width W2 of the drain-side extension portion 22B is approximately 0.6 μm. It is preferable that the width of the source-side extension portion 22A be smaller than the width of the gate layer 26, and the width of the drain-side extension portion 22B be larger than the width of the gate layer 26. For example, the width W1 of the source-side extension portion 22A is approximately 0.4 times the width of the gate layer 26, and the width W2 of the drain-side extension portion 22B is approximately 1.2 times the width of the gate layer 26.

The top surface of the source-side extension portion 22A is covered by the first passivation layer 24 throughout the entire width W1. Therefore, the first passivation layer 24 protects the source-side extension portion 22A from process damage, and the source-side extension portion 22A is maintained at a uniform thickness. Similarly, the top surface of the drain-side extension portion 22B is covered by the first passivation layer 24 throughout the entire width W2. Therefore, the first passivation layer 24 protects the drain-side extension portion 22B from process damage, and the drain-side extension portion 22B is maintained at a uniform thickness.

The thickness of the source-side extension portion 22A and the thickness of the drain-side extension portion 22B are the same as the thickness of the base portion 22C. That is, the thickness of the step layer 22 is constant in all of the source-side extension portion 22A, the drain-side extension portion 22B, and the base portion 22C. The thickness of the step layer 22 can be, for example, equal to or greater than 10 nm and equal to or smaller than 30 nm. In the first embodiment, the thickness of the step layer 22 is equal to or smaller than 25 nm, preferably, equal to or smaller than 15 nm.

The first passivation layer 24 can be formed from, for example, a silicon dioxide (SiO₂) layer or a silicon nitride (SiN) layer. The first passivation layer 24 is an SiO₂ layer in the first embodiment. The first passivation layer 24 includes an opening portion 24A going through the first passivation layer 24, in the same region as the gate layer 26 in plan view. Therefore, the first passivation layer 24 is formed on the source-side extension portion 22A and the drain-side extension portion 22B of the step layer 22 and is not formed on the base portion 22C positioned just below the gate layer 26. The first passivation layer 24 is formed on the extension portions 22A and 22B of the step layer 22 and is not formed on the top surface of the gate layer 26 in the first embodiment.

The thickness of the first passivation layer 24 can be, for example, equal to or greater than 30 nm and equal to or smaller than 200 nm. In the first embodiment, the thickness of the first passivation layer 24 is larger than the thickness of the step layer 22, and the thickness is, for example, approximately 50 nm. However, the thickness is not limited to this. The thickness of the first passivation layer 24 and the thickness of the step layer 22 may be the same, or the thickness of the step layer 22 may be larger than the thickness of the first passivation layer 24.

The gate layer 26 includes a nitride semiconductor, and the gate layer 26 is a GaN layer doped with acceptor impurities (p-type GaN layer) in the first embodiment. The band gap of the gate layer 26 that is a p-type GaN layer is smaller than the band gap of the step layer 22 that is an AlGaN layer. The gate layer 26 is formed on part of the step layer 22. The gate layer 26 is formed in the same region as the opening portion 24A of the first passivation layer 24 in plan view. The gate layer 26 has a trapezoidal, rectangular, or ridge-shaped cross section. The width of the gate layer 26 can be, for example, equal to or greater than 0.4 μm and equal to or smaller than 1 μm. The width (for example, bottom width) of the gate layer 26 is approximately 0.5 μm in the first embodiment. As described above, the width of the gate layer 26 is the same as the width of the base portion 22C of the step layer 22.

The thickness of the gate layer 26 can be, for example, equal to or greater than 100 nm and equal to or smaller than 140 nm. The thickness of the gate layer 26 is, for example, approximately 110 nm. the thickness of the gate layer 26 is larger than the thickness of the step layer 22. Preferably, the thickness of the gate layer 26 can be equal to or greater than four times the thickness of the step layer 22.

The concentration of the acceptor impurities doped into the gate layer 26 can be equal to or greater than 1×10¹⁹ cm⁻³ and equal to or smaller than 3×10¹⁹ cm⁻³. For example, the acceptor impurities contain magnesium (Mg) with average concentration of approximately 2×10¹⁹ cm⁻³ in the first embodiment. However, in place of Mg or in addition to Mg, the acceptor impurities may contain at least one of zinc (Zn) and C. The gate layer 26 is provided to deplete the 2DEG 20 formed in the electron transit layer 16 in the region just below the gate layer 26.

FIG. 2 is a partially enlarged cross-sectional view of the nitride semiconductor apparatus 10 in FIG. 1. As described above, although the step layer 22 is formed as an undoped layer, the base portion 22C of the step layer 22 may include a small amount of acceptor impurities diffused from the gate layer 26 as indicated by a dot hatch in FIG. 2. For example, the base portion 22C can contain Mg diffused from the gate layer 26 in the first embodiment. The concentration of the acceptor impurities that can be included in the step layer 22 is in the order of 10¹⁸ cm⁻³ at most, and the concentration is lower than the concentration of the acceptor impurities doped into the gate layer 26. The step layer 22 can be formed as an undoped layer to sufficiently reduce the concentration of the acceptor impurities included in the step layer 22 to thereby suppress the depletion of the 2DEG 20 just below the source-side extension portion 22A and the drain-side extension portion 22B. This can prevent a rise in on-resistance of the nitride semiconductor apparatus 10.

With reference again to FIG. 1, the gate electrode 28 is formed on the gate layer 26. Although the gate electrode 28 is formed on part of the gate layer 26 in FIG. 1, the arrangement is not limited to this. The gate electrode 28 may be formed on the entire top surface of the gate layer 26. The gate electrode 28 and the gate layer 26 form a Schottky junction. The gate electrode 28 includes one or a plurality of metal layers, and the gate electrode 28 is, for example, a titanium nitride (TiN) layer in the first embodiment. Alternatively, the gate electrode 28 may include a first metal layer containing Ti and a second metal layer containing TiN provided on the first metal layer. The thickness of the gate electrode 28 can be, for example, equal to or greater than 50 nm and equal to or smaller than 300 nm.

The second passivation layer 30 covers the electron supply layer 18, the step layer 22, the gate layer 26, and the gate electrode 28. The second passivation layer 30 can include, for example, a single film of one of an SiN film, an SiO₂ film, a silicon oxynitride (SiON) film, an alumina (Al₂O₃) film, an AlN film, and an aluminum oxynitride (AlON) film or can include a composite film with any combination of two or more of these films. For example, the second passivation layer 30 is an SiN layer in the first embodiment. The second passivation layer 30 directly covers the top surface of part of the electron supply layer 18, the side surface of the step layer 22, the side surface and the top surface of the first passivation layer 24, the side surface and the top surface of the gate layer 26, and the side surface and the top surface of the gate electrode 28 in the first embodiment.

The source electrode 32 and the drain electrode 34 include one or a plurality of metal layers. The source electrode 32 includes a source electrode portion 32A and a source field plate portion 32B continuous to the source electrode portion 32A.

The source electrode portion 32A includes a filled region that fills the source contact hole 30A; and an upper region integrated with the filled region and positioned in a peripheral region of the source contact hole 30A and a region above the gate electrode 28 in plan view. The source field plate portion 32B is integrated with the upper region of the source electrode portion 32A and is provided on the second passivation layer 30 so as to cover the step layer 22 in plan view. The source field plate portion 32B includes an end portion 32C near the drain electrode 34, and the end portion 32C is positioned between the drain electrode 34 and the step layer 22 in plan view. The distance from the end portion of the gate layer 26 to the end portion 32C of the source field plate portion 32B (length of the source field plate portion 32B) in the direction along the X-axis of FIG. 1 is defined as a source field plate length. The source field plate portion 32B plays a role of extending the depletion layer to the region just below the source field plate portion 32B to mitigate the electric field concentration near the end portion of the gate electrode 28 during zero bias in which the gate voltage is not applied to the gate electrode 28. Note that, to increase the effect of the source field plate portion 32B, the width W2 of the drain-side extension portion 22B of the step layer 22 is set to a value equal to or smaller than the source field plate length.

(Manufacturing Method)

A manufacturing method of the nitride semiconductor apparatus 10 in FIG. 1 will be described.

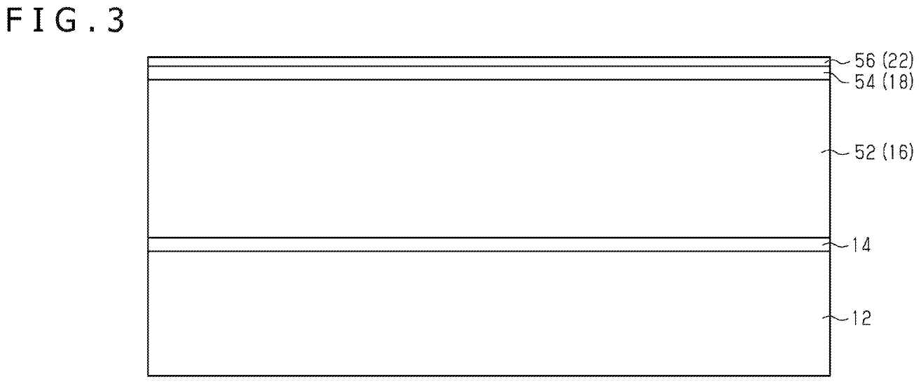

FIGS. 3 to 10 are schematic cross-sectional views illustrating exemplary manufacturing processes of the nitride semiconductor apparatus 10. Note that, in FIGS. 3 to 10, some of the reference signs in FIG. 1 is indicated in parentheses for members including final constituent elements of the nitride semiconductor apparatus 10 or for members corresponding to the final constituent elements, in order to facilitate the understanding.

As illustrated in FIG. 3, the buffer layer 14, a first nitride semiconductor layer 52, a second nitride semiconductor layer 54, and a third nitride semiconductor layer 56 are sequentially formed on the substrate 12 that is, for example, an Si substrate. The metal organic chemical vapor deposition (MOCVD) method can be used to epitaxially grow the buffer layer 14, the first nitride semiconductor layer 52, the second nitride semiconductor layer 54, and the third nitride semiconductor layer 56.

Although not illustrated in detail, the buffer layer 14 is, for example, a multi-layer buffer layer in the first embodiment. An AlN layer (first buffer layer) is formed on the substrate 12, and then a graded AlGaN layer (second buffer layer) is formed on the AlN layer. The graded AlGaN layer is formed by, for example, laminating three AlGaN layers with Al compositions of 75%, 50%, and 25% from the side closest to the AlN layer.

The manufacturing method of the nitride semiconductor apparatus 10 includes forming the first nitride semiconductor layer 52 and forming the second nitride semiconductor layer 54. In the first embodiment, a GaN layer is formed as the first nitride semiconductor layer 52 on the buffer layer 14, and an AlGaN layer is formed as the second nitride semiconductor layer 54 on the first nitride semiconductor layer 52. The band gap of the second nitride semiconductor layer 54 is larger than the band gap of the first nitride semiconductor layer 52. The first nitride semiconductor layer 52 corresponds to the electron transit layer 16 in FIG. 1, and the second nitride semiconductor layer 54 corresponds to the electron supply layer 18 in FIG. 1.

The manufacturing method of the nitride semiconductor apparatus 10 includes forming, on the second nitride semiconductor layer 54, the third nitride semiconductor layer 56 with the band gap smaller than the band gap of the second nitride semiconductor layer 54. As a result, a GaN layer is formed as the third nitride semiconductor layer 56 on the second nitride semiconductor layer 54.

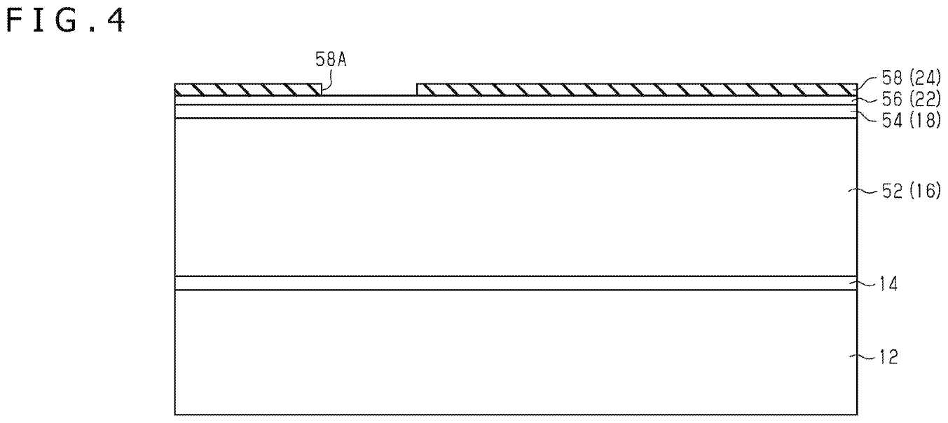

FIG. 4 is a schematic cross-sectional view illustrating a manufacturing process following FIG. 3. As illustrated in FIG. 4, the manufacturing method of the nitride semiconductor apparatus 10 includes forming a first dielectric layer 58 on the third nitride semiconductor layer 56 and forming an opening portion 58A on the first dielectric layer 58. In the first embodiment, the opening portion 58A corresponds to a “first opening portion.” As a result, the first dielectric layer 58 including the opening portion 58A is formed on the third nitride semiconductor layer 56.

For example, the first dielectric layer 58 is an SiO₂ layer formed by the plasma CVD method in the first embodiment. The first dielectric layer 58 is formed on the third nitride semiconductor layer 56, and then the first dielectric layer 58 is selectively removed by lithography or etching to form the opening portion 58A going through the first dielectric layer 58. A mask is formed on the surface of the first dielectric layer 58 except for the region provided with the opening portion 58A, and an etchant containing, for example, hydrofluoric acid (HF) can be used to perform wet etching to pattern the first dielectric layer 58.

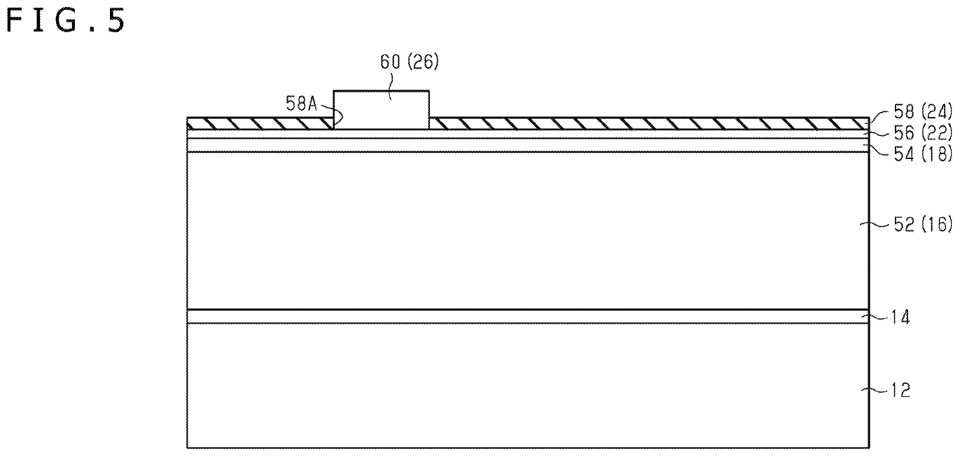

FIG. 5 is a schematic cross-sectional view illustrating a manufacturing process following FIG. 4. As illustrated in FIG. 5, the manufacturing method of the nitride semiconductor apparatus 10 includes forming a fourth nitride semiconductor layer 60 containing acceptor impurities on the second nitride semiconductor layer 54 or the third nitride semiconductor layer 56 in the same region as the opening portion 58A in plan view. In the first embodiment, the fourth nitride semiconductor layer 60 is formed on the third nitride semiconductor layer 56 exposed by the opening portion 58A. The fourth nitride semiconductor layer 60 corresponds to the gate layer 26 in FIG. 1.

For example, the MOCVD method is used to epitaxially grow the fourth nitride semiconductor layer 60 that is a p-type GaN layer in the first embodiment. The epitaxial growth is possible when the difference between the lattice constant of the base material and the lattice constant of the material of the film to be grown is relatively small. Therefore, the fourth nitride semiconductor layer 60 (for example, p-type GaN layer) is epitaxially grown on the third nitride semiconductor layer 56 (for example, GaN layer) with substantially the same lattice constant and is not epitaxially grown on the first dielectric layer 58 (for example, SiO₂ layer) with a relatively different lattice constant. Therefore, the fourth nitride semiconductor layer 60 can be selectively grown on the third nitride semiconductor layer 56 exposed in the opening portion 58A.

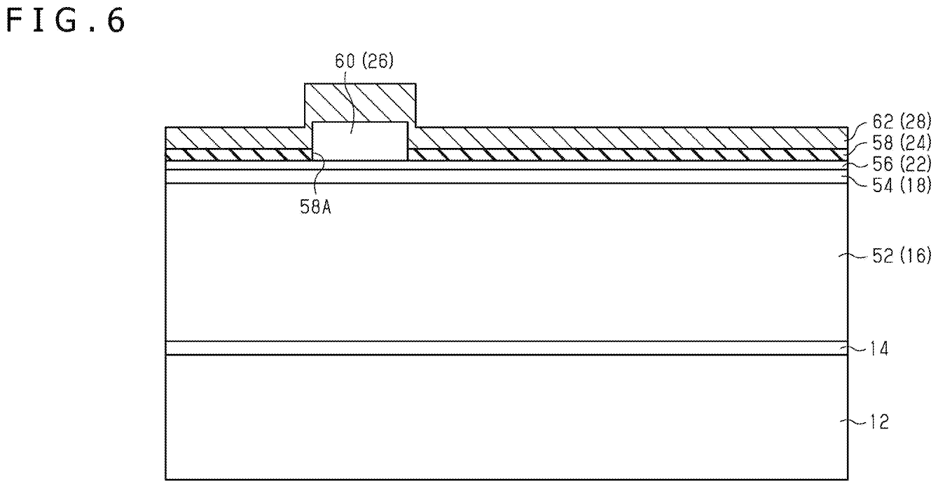

FIG. 6 is a schematic cross-sectional view illustrating a manufacturing process following FIG. 5. The manufacturing method of the nitride semiconductor apparatus 10 includes forming the gate electrode 28 on the fourth nitride semiconductor layer 60.

More specifically, the manufacturing method of the nitride semiconductor apparatus 10 includes forming a metal layer 62 so as to cover the entire exposed surfaces of the first dielectric layer 58 and the fourth nitride semiconductor layer 60 as illustrated in FIG. 6. In the first embodiment, the sputtering method is used to form, for example, a TiN layer as the metal layer 62.

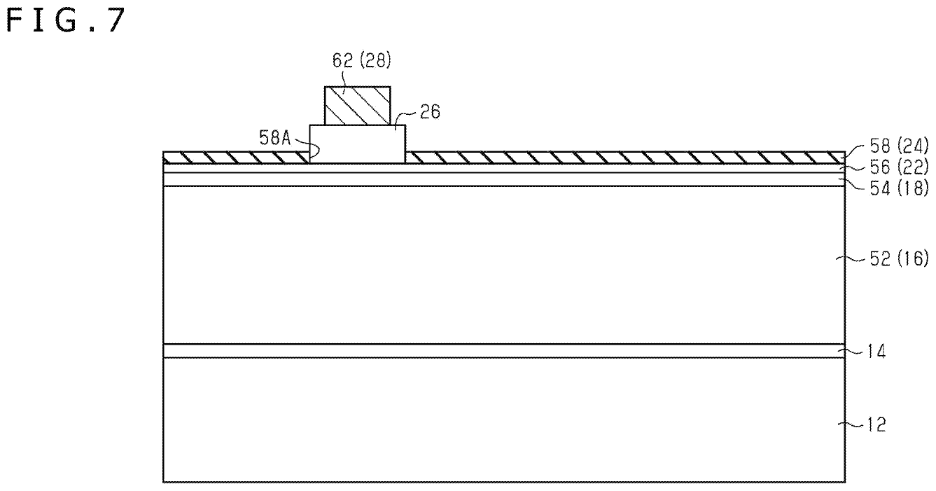

FIG. 7 is a schematic cross-sectional view illustrating a manufacturing process following FIG. 6. As illustrated in FIG. 7, the manufacturing method of the nitride semiconductor apparatus 10 includes selectively removing the metal layer 62. The metal layer 62 is selectively removed by lithography or etching to form the gate electrode 28 of FIG. 1. The gate electrode 28 is formed on the gate layer 26. In this case, the third nitride semiconductor layer 56 is covered by the first dielectric layer 58 and is thus protected from process damage caused by, for example, plasma exposure.

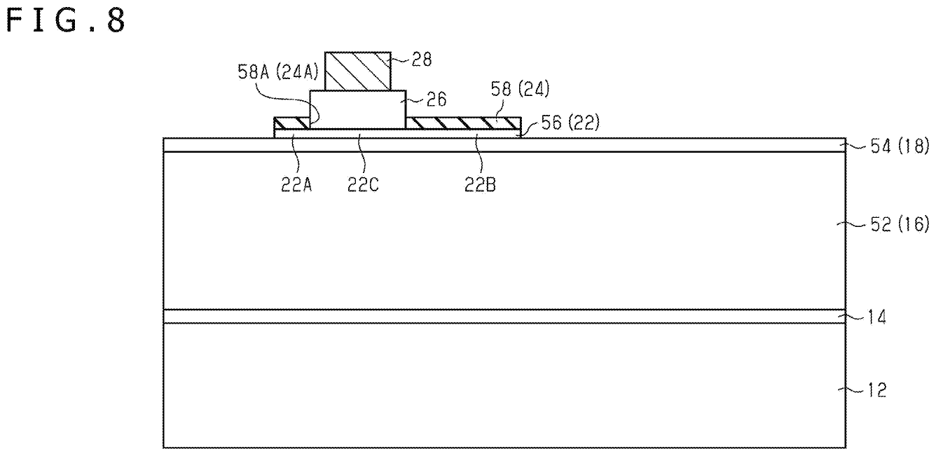

FIG. 8 is a schematic cross-sectional view illustrating a manufacturing process following FIG. 7. As illustrated in FIG. 8, the manufacturing method of the nitride semiconductor apparatus 10 includes selectively removing the first dielectric layer 58 and the third nitride semiconductor layer 56. As a result, the first passivation layer 24 and the step layer 22 of FIG. 1 are formed.

For example, a mask is formed in the region corresponding to the first passivation layer 24 and the step layer 22, and the mask is used to perform etching (for example, dry etching with at least one of Cl₂, SiCl₄, CF₄, and O₂) to sequentially pattern the first dielectric layer 58 and the third nitride semiconductor layer 56. The mask is then stripped.

The etching process of the first dielectric layer 58 and the third nitride semiconductor layer 56 may include a plurality of etching processes. For example, the first dielectric layer 58 is etched in a first etching process, and the third nitride semiconductor layer 56 is etched in the second etching process. In this case, the etching conditions of the first etching process are selected from the viewpoint of reducing the etching time of the entire first dielectric layer 58 and third nitride semiconductor layer 56, while the etching conditions of the second etching process are determined such that the third nitride semiconductor layer 56 is etched at a higher etching rate than the etching rate of the second nitride semiconductor layer 54. For example, the etching conditions are determined in the second etching process such that the etching selectivity between the third nitride semiconductor layer 56 and the second nitride semiconductor layer 54 is at least 10 or more, preferably, 20 or more. This suppresses undesirable etching of the second nitride semiconductor layer 54 (electron supply layer 18) in the etching process of the third nitride semiconductor layer 56.

The etching process of the first dielectric layer 58 and the third nitride semiconductor layer 56 is a process of selectively etching the third nitride semiconductor layer 56 so as to form the source-side extension portion 22A and the drain-side extension portion 22B that extend outside of the fourth nitride semiconductor layer 60 in plan view. As a result, the step layer 22 including the source-side extension portion 22A and the drain-side extension portion 22B is formed.

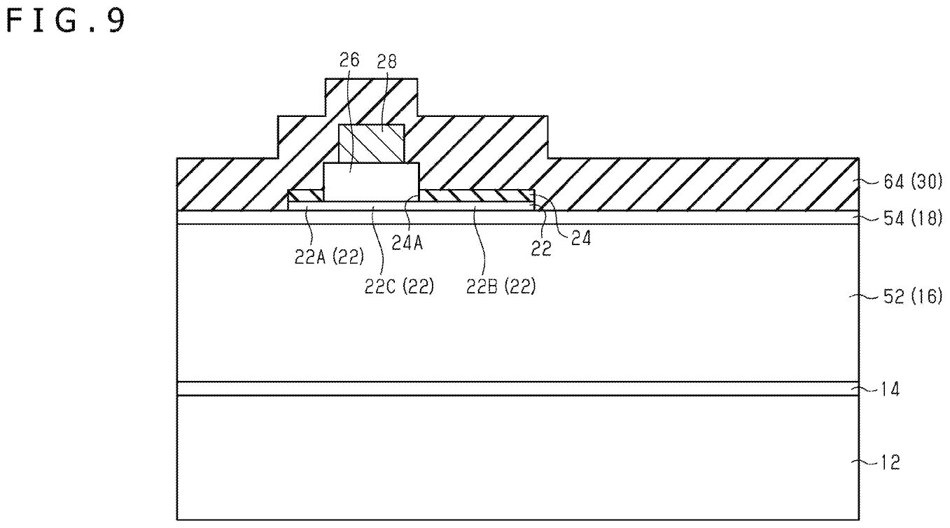

FIG. 9 is a schematic cross-sectional view illustrating a manufacturing process following FIG. 8. As illustrated in FIG. 9, the manufacturing method of the nitride semiconductor apparatus 10 includes forming a second dielectric layer 64. As a result, the second dielectric layer 64 is formed to cover the entire exposed surfaces of the step layer 22, the first passivation layer 24, the gate layer 26, the gate electrode 28, and the second nitride semiconductor layer 54.

For example, the low-pressure chemical vapor deposition (LPCVD) method is used to form an SiN layer as the second dielectric layer 64 to cover the surfaces of the step layer 22, the first passivation layer 24, the gate layer 26, the gate electrode 28, and the second nitride semiconductor layer 54 in the first embodiment. The LPCVD method is used instead of the plasma CVD method to suppress the exposure of the etching surface to plasm in the film formation of the second dielectric layer 64, and this can reduce the process damage. The second dielectric layer 64 corresponds to the second passivation layer 30 in FIG. 1.

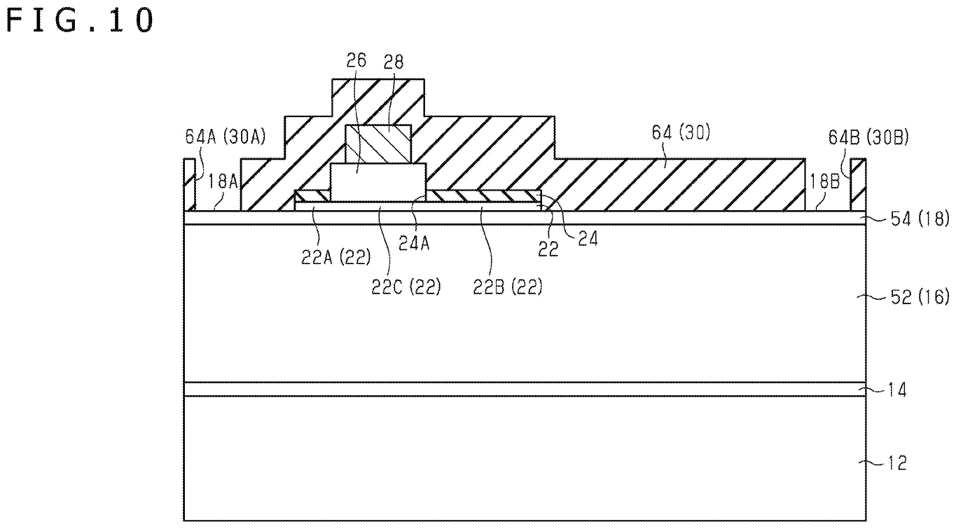

FIG. 10 is a schematic cross-sectional view illustrating a manufacturing process following FIG. 9. The manufacturing method of the nitride semiconductor apparatus 10 includes forming the source electrode 32 and the drain electrode 34 in contact with the second nitride semiconductor layer 54. The electrode formation process includes forming contact holes 64A and 64B going through the second dielectric layer 64 as illustrated in FIG. 10. For example, the source contact hole 30A and the drain contact hole 30B that expose part of the top surface of the electron supply layer 18 as the source contact 18A and the drain contact 18B, respectively, are formed on the second dielectric layer 64 in the first embodiment. The second dielectric layer 64, the contact hole 64A, and the contact hole 64B correspond to the second passivation layer 30, the source contact hole 30A, and the drain contact hole 30B in FIG. 1, respectively. The electrode formation process further includes forming a metal layer filling the contact holes 64A and 64B and covering the entire exposed surface of the second dielectric layer 64; and patterning the metal layer by lithography and etching. As a result, the source electrode 32 and the drain electrode 34 of FIG. 1 are formed. The nitride semiconductor apparatus 10 of FIG. 1 is obtained by the processes described above.

An action of the nitride semiconductor apparatus 10 in the first embodiment will be described.

The gate layer 26 including a p-type GaN layer is positioned below the gate electrode 28 in the nitride semiconductor apparatus 10 of the first embodiment. According to this configuration, the acceptor impurities included in the gate layer 26 raise the energy level of the electron transit layer 16 and the electron supply layer 18. Therefore, the energy level of the conduction band of the electron transit layer 16 near the heterojunction interface between the electron transit layer 16 and the electron supply layer 18 is substantially the same as or larger than the Fermi level in the region just below the gate layer 26. Therefore, the 2DEG 20 is not formed on the electron transit layer 16 in the region just below the gate layer 26 during zero bias in which the voltage is not applied to the gate electrode 28. On the other hand, the 2DEG is formed on the electron transit layer 16 in the region other than the region just below the gate layer 26. This realizes the normally-off operation. Once an appropriate ON voltage is applied to the gate electrode 28, a channel is formed in the electron transit layer 16 in the region just below the gate electrode 28, and the source and the drain are conducted.

When a positive bias is applied to the gate electrode 28, holes are injected from the gate electrode 28 to the gate layer 26. The nitride semiconductor apparatus 10 provided with the step layer 22 can disperse the injected holes to the step layer 22 including the source-side extension portion 22A and the drain-side extension portion 22B. Therefore, the hole density in the interface between the step layer 22 and the electron supply layer 18 is reduced compared to the case in which the extension portions 22A and 22B are not provided. This suppresses the band bending of the electron supply layer 18 caused by the hole storage, and the movement of electrons, that is, gate leakage current, from the electron transit layer 16 to the gate layer 26 is suppressed.

The source-side extension portion 22A and the drain-side extension portion 22B are formed as undoped layers. Therefore, the concentration of the acceptor impurities included in the extension portions 22A and 22B is sufficiently low, and this can suppress the depletion of the 2DEG 20 caused by the extension portions 22A and 22B. This means that unnecessary depletion of the 2DEG in the region just below the extension portions 22A and 22B is suppressed.

When a high voltage is applied between the drain and the source while the transistor is in the off-state, electrons are trapped in a crystal defect or a layer interface in the transistor, such as in the electron transit layer and on the surface of the electron supply layer, and the electrons inhibit the generation of the two-dimensional electron gas. In this case, it is known that the on-resistance is increased the next time the transistor is switched to the on-state, and this phenomenon is called current collapse.

In the nitride semiconductor apparatus 10, the step layer 22 wider than the gate layer 26 is provided below the gate layer 26, and the surface of the electron supply layer 18 near the gate layer 26 is thus not exposed to the etching gas. Further, the existence of the first passivation layer 24 on the extension portions 22A and 22B of the step layer 22 can increase the physical distance between the etching surface (surface of the first passivation layer 24 exposed to the etching gas) and the 2DEG 20 compared to the case in which the first passivation layer 24 does not exist. The electrons are relatively easily trapped on the etching surface. Therefore, the influence on the 2DEG 20 caused by the electrons trapped on the etching surface near the gate layer 26 can be reduced, and the generation of the current collapse is suppressed.

In addition, the gate layer 26 is selectively grown on the third nitride semiconductor layer 56 in the nitride semiconductor apparatus 10. Therefore, the gate layer 26 does not have to be patterned by dry etching, and this reduces the occurrence of etching damage in the nitride semiconductor apparatus 10.

Further, the third nitride semiconductor layer 56 is covered by the first dielectric layer 58 in forming the gate electrode 28. This can reduce the occurrence of process damage in the step layer 22 formed from part of the third nitride semiconductor layer 56 and can precisely control the thickness of the step layer 22.

The first embodiment has the following effects.

(1-1) The nitride semiconductor apparatus 10 includes the step layer 22 including a nitride semiconductor with a band gap smaller than the band gap of the electron supply layer 18. The step layer 22 includes the source-side extension portion 22A and the drain-side extension portion 22B that extend outside of the gate layer 26 in plan view. Each of the extension portions 22A and 22B includes an undoped layer. According to this configuration, the depletion of the 2DEG 20 in the region just below the source-side extension portion 22A and the drain-side extension portion 22B is suppressed, and the hole density in the interface between the step layer 22 and the electron supply layer 18 is reduced. This suppresses the band bending of the electron supply layer 18 caused by the hole storage and prevents the movement of electrons from the electron transit layer 16 to the gate layer 26. Therefore, a rise in on-resistance can be suppressed, and the gate leakage current can be reduced to improve the gate withstand voltage in the nitride semiconductor apparatus.

(1-2) The nitride semiconductor apparatus 10 includes the first passivation layer 24 formed on the source-side extension portion 22A and the drain-side extension portion 22B. According to this configuration, the third nitride semiconductor layer 56 corresponding to the step layer 22 is covered by the first dielectric layer 58 corresponding to the first passivation layer 24 in forming the gate electrode 28. This can prevent the generation of the current collapse caused by process damage, thereby improving the reliability regarding the voltage stress between the drain and the source.

(1-3) The nitride semiconductor apparatus 10 includes the first passivation layer 24 formed on the source-side extension portion 22A and the drain-side extension portion 22B. According to this configuration, the third nitride semiconductor layer 56 corresponding to the step layer 22 is covered by the first dielectric layer 58 corresponding to the first passivation layer 24 in forming the gate electrode 28. This can precisely control the thickness of the step layer 22 and improve the yield in manufacturing the nitride semiconductor apparatus 10.

### Second Embodiment

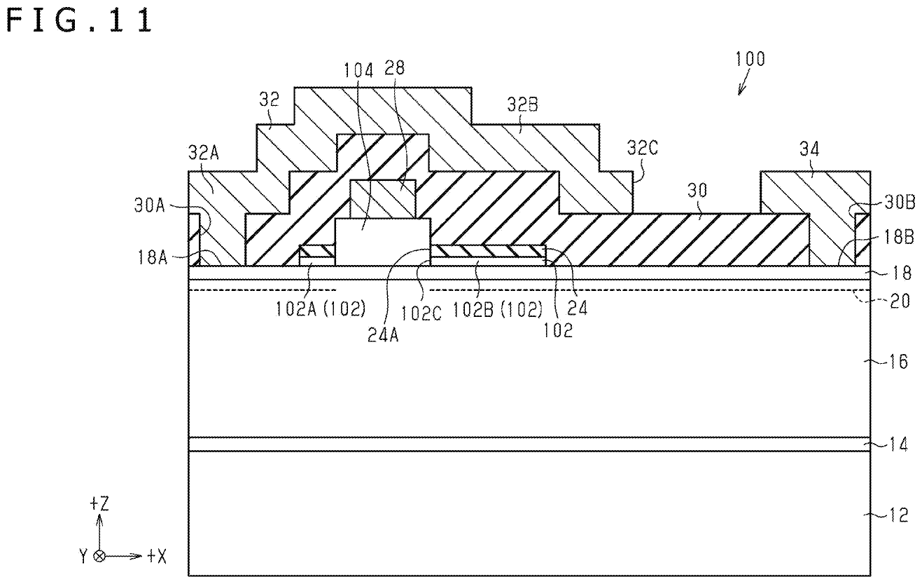

FIG. 11 is a schematic cross-sectional view of an exemplary nitride semiconductor apparatus 100 according to a second embodiment. In FIG. 11, the same reference signs as the reference signs in the first embodiment are provided to constituent elements similar to the constituent elements in the first embodiment, and the description will not be repeated.

The nitride semiconductor apparatus 100 of the second embodiment includes a step layer 102 formed on part of the electron supply layer 18; and a gate layer 104 that is formed on part of the electron supply layer 18 and includes a nitride semiconductor containing acceptor impurities. The step layer 102 includes an opening portion 102C. The gate layer 26 is formed on the step layer 22 in the first embodiment. The second embodiment is different from the first embodiment in that the gate layer 104 is formed on the electron supply layer 18 in the opening portion 102C.

The step layer 102 of the second embodiment includes a source-side extension portion 102A and a drain-side extension portion 102B corresponding to the source-side extension portion 22A and the drain-side extension portion 22B of the step layer 22 in the first embodiment, respectively; and the opening portion 102C going through the step layer 102. The opening portion 102C is arranged in the same region as the gate layer 104 in plan view. The opening portion 102C is positioned between the source-side extension portion 102A and the drain-side extension portion 102B in the direction along the X-axis in FIG. 11. The opening portion 102C communicates with the opening portion 24A of the first passivation layer 24, and the width of the opening portion 102C is the same as the width of the gate layer 104 in the direction along the X-axis in FIG. 11. The width of the opening portion 102C can be, for example, equal to or greater than 0.4 μm and equal to or smaller than 1 μm. The width of the opening portion 102C is approximately 0.5 μm in the second embodiment. The configuration and the features of the step layer 102 in the second embodiment can be similar to those of the step layer 22 in the first embodiment except that the step layer 102 includes the opening portion 102C.

The gate layer 104 is formed on part of the electron supply layer 18. The gate layer 104 is formed in the same region as the opening portion 24A of the first passivation layer 24 and the opening portion 102C of the step layer 102 in plan view. The configuration and the features of the gate layer 104 in the second embodiment can be similar to those of the gate layer 26 in the first embodiment except that the gate layer 104 is formed on the electron supply layer 18.

(Manufacturing Method)

A manufacturing method of the nitride semiconductor apparatus 100 in FIG. 11 will be described.

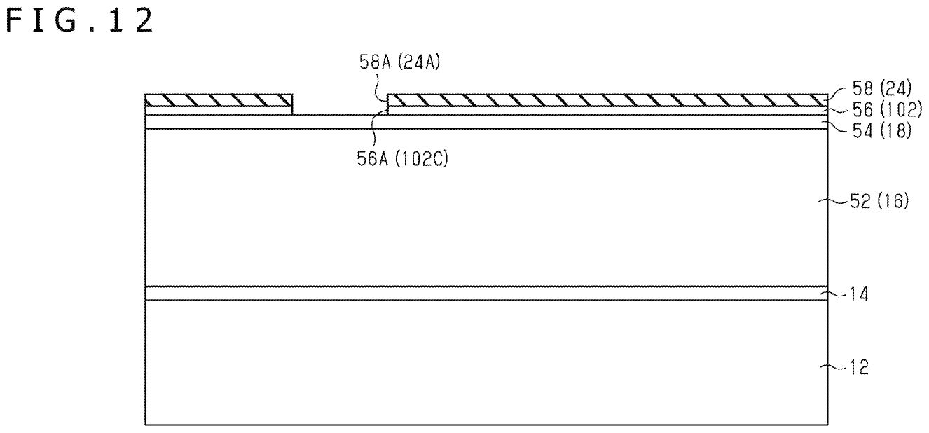

FIG. 12 is a schematic cross-sectional view illustrating an exemplary manufacturing process of the nitride semiconductor apparatus 100. Note that, in FIG. 12, part of the reference signs in FIG. 11 is indicated in parentheses for members including final constituent elements of the nitride semiconductor apparatus 100 or for members corresponding to the final constituent elements, in order to facilitate the understanding.

FIG. 12 illustrates a change example of the manufacturing process in the first embodiment illustrated in FIG. 4 and is a schematic cross-sectional view illustrating a manufacturing processing following FIG. 3. As illustrated in FIG. 12, the manufacturing method of the nitride semiconductor apparatus 100 includes forming an opening portion 56A communicating with the opening portion 58A on the third nitride semiconductor layer 56 to expose part of the second nitride semiconductor layer 54; and forming the fourth nitride semiconductor layer 60 on the second nitride semiconductor layer 54 exposed by the opening portion 56A. In the second embodiment, the opening portion 58A corresponds to the “first opening portion,” and the opening portion 56A corresponds to a “second opening portion.” More specifically, the first dielectric layer 58 is formed on the third nitride semiconductor layer 56, and then the first dielectric layer 58 and the third nitride semiconductor layer 56 are selectively removed by lithography and etching. As a result, the opening portion 58A going through the first dielectric layer 58 and the opening portion 56A going through the third nitride semiconductor layer 56 and communicating with the opening portion 58A are formed, and part of the second nitride semiconductor layer 54 is exposed through the opening portion 58A and the opening portion 56A. The third nitride semiconductor layer 56 corresponds to the step layer 102 in FIG. 11.

A process similar to the process in the first embodiment can be applied to the subsequent manufacturing process. In the first embodiment, the fourth nitride semiconductor layer 60 is selectively formed on the third nitride semiconductor layer 56 exposed through the opening portion 58A (see FIG. 5). In the second embodiment, the fourth nitride semiconductor layer 60 is selectively formed on the second nitride semiconductor layer 54 exposed through the opening portion 58A and the opening portion 56A. The fourth nitride semiconductor layer 60 corresponds to the gate layer 104 of FIG. 11.

Note that, in the second embodiment, the fourth nitride semiconductor layer 60 (for example, p-type GaN layer) is epitaxially grown on the second nitride semiconductor layer (for example, AlGaN layer) with a relatively close lattice constant and is not epitaxially grown on the first dielectric layer 58 (for example, SiO₂ layer) with a relatively different lattice constant. Therefore, the fourth nitride semiconductor layer 60 can be selectively grown on the second nitride semiconductor layer 54 exposed in the opening portion 58A and the opening portion 56A. The subsequent processes are similar to the processes in FIGS. 6 to 10, and the description will not be repeated.

An action of the nitride semiconductor apparatus 100 in the second embodiment different from the action of the nitride semiconductor apparatus 10 in the first embodiment will be described.

In the nitride semiconductor apparatus 100 of the second embodiment, the gate layer 104 is directly formed on the electron supply layer 18 unlike in the first embodiment. This means that the distance between the gate layer 104 and the 2DEG 20 is shorter than that in the case of the first embodiment. As a result, the function of the gate layer 104 that depletes the 2DEG 20 formed on the electron transit layer 16 is enhanced in the region just below the gate layer 104.

The second embodiment has the following effect in addition to the effects of the first embodiment.

(2-1) The gate layer 104 is formed on the electron supply layer 18. According to this configuration, the distance between the gate layer 104 and the 2DEG 20 is reduced, and the threshold voltage of the nitride semiconductor apparatus 100 can be raised.

### Third Embodiment

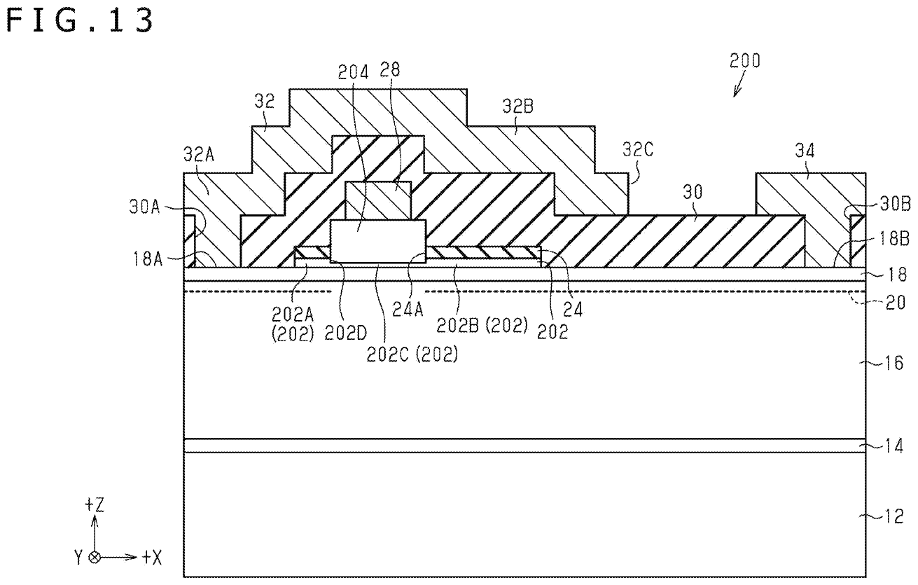

FIG. 13 is a schematic cross-sectional view of an exemplary nitride semiconductor apparatus 200 according to a third embodiment. In FIG. 13, the same reference signs as the reference signs in the first embodiment are provided to constituent elements similar to the constituent elements in the first embodiment, and the description will not be repeated.

The nitride semiconductor apparatus 200 of the third embodiment includes a step layer 202 formed on part of the electron supply layer 18; and a gate layer 204 including a nitride semiconductor containing acceptor impurities. The step layer 202 includes a source-side extension portion 202A and a drain-side extension portion 202B; and a base portion 202C adjacent to the source-side extension portion 202A and the drain-side extension portion 202B. The gate layer 204 is formed on the base portion 202C having a thickness smaller than the thickness of each of the source-side extension portion 202A and the drain-side extension portion 202B. In the first embodiment, the gate layer 26 is formed on the base portion 22C with the same thickness as the thickness of each of the source-side extension portion 22A and the drain-side extension portion 22B. The third embodiment is different from the first embodiment in that the gate layer 204 is formed on the base portion 202C having a thickness smaller than the thickness of each of the source-side extension portion 202A and the drain-side extension portion 202B.

The source-side extension portion 202A and the drain-side extension portion 202B of the step layer 202 in the third embodiment correspond to the source-side extension portion 22A and the drain-side extension portion 22B of the step layer 22 in the first embodiment, respectively. Unlike the base portion 22C in the first embodiment, the thickness of the base portion 202C in the third embodiment is smaller than the thickness of each of the source-side extension portion 202A and the drain-side extension portion 202B. As a result, a recess portion 202D is formed.

The recess portion 202D communicates with the opening portion 24A of the first passivation layer 24, and therefore, the width of the recess portion 202D is the same as the width of the gate layer 204 in the direction along the X-axis in FIG. 13. The configuration and the features of the step layer 202 in the third embodiment can be similar to those of the step layer 22 in the first embodiment except that the step layer 202 includes the recess portion 202D.

The gate layer 204 is formed on the base portion 202C of the step layer 202, that is, on the recess portion 202D. The gate layer 204 is formed in the same region as the opening portion 24A of the first passivation layer 24 and the base portion 202C of the step layer 202 in plan view. The configuration and the features of the gate layer 204 in the third embodiment can be similar to those of the gate layer 26 in the first embodiment except that the gate layer 204 is formed on the recess portion 202D of the step layer 202.

(Manufacturing Method)

A manufacturing method of the nitride semiconductor apparatus 200 in FIG. 13 will be described.

The manufacturing method of the nitride semiconductor apparatus 200 includes forming the recess portion (corresponds to the recess portion 202D in FIG. 13) communicating with the opening portion 58A on the third nitride semiconductor layer 56; and forming the fourth nitride semiconductor layer 60 on the recess portion. The manufacturing method of the nitride semiconductor apparatus 200 in the third embodiment is different from the manufacturing method of the nitride semiconductor apparatus 100 in the second embodiment in that the recess portion not going through the third nitride semiconductor layer 56 is formed in the manufacturing process illustrated in FIG. 12, instead of forming the opening portion 56A going through the third nitride semiconductor layer 56.

In the third embodiment, the fourth nitride semiconductor layer 60 (for example, p-type GaN layer) is epitaxially grown on the third nitride semiconductor layer 56 (for example, GaN layer) with substantially the same lattice constant, as in the first embodiment. The subsequent manufacturing processes are similar to the processes in FIGS. 6 to 10, and the description will not be repeated.

An action of the nitride semiconductor apparatus 200 in the third embodiment different from the action of the nitride semiconductor apparatus 10 in the first embodiment will be described.

In the nitride semiconductor apparatus 200 of the third embodiment, the gate layer 204 is formed on the base portion 202C having a thickness smaller than the thickness of each of the source-side extension portion 202A and the drain-side extension portion 202B, unlike in the first embodiment. This means that the distance between the gate layer 204 and the 2DEG 20 is shorter than that in the case of the first embodiment. As a result, the function of the gate layer 204 that depletes the 2DEG 20 formed on the electron transit layer 16 is enhanced in the region just below the gate layer 204.

The third embodiment has the following effect in addition to the effects of the first embodiment.

(3-1) The step layer 202 includes the base portion 202C having a thickness smaller than the thickness of each of the source-side extension portion 202A and the drain-side extension portion 202B and being adjacent to the source-side extension portion 202A and the drain-side extension portion 202B. The gate layer 204 is formed on the base portion 202C. According to this configuration, the distance between the gate layer 204 and the 2DEG 20 is reduced, and the threshold voltage of the nitride semiconductor apparatus 200 can be raised.

### Fourth Embodiment

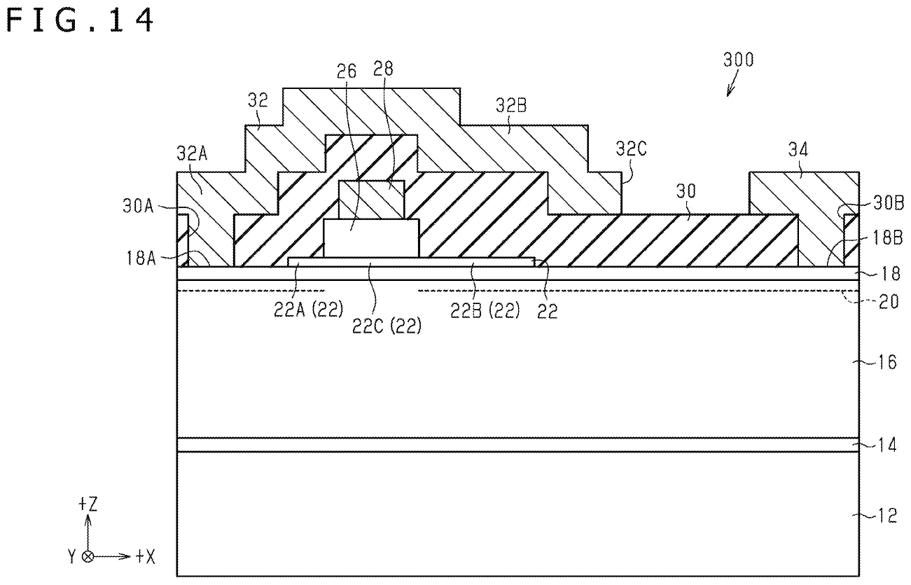

FIG. 14 is a schematic cross-sectional view of an exemplary nitride semiconductor apparatus 300 according to a fourth embodiment. In FIG. 14, the same reference signs as the reference signs in the first embodiment are provided to constituent elements similar to the constituent elements in the first embodiment, and the description will not be repeated.

The nitride semiconductor apparatus 300 of the fourth embodiment is different from the nitride semiconductor apparatus 10 of the first embodiment in that the nitride semiconductor apparatus 300 does not include the first passivation layer 24. Therefore, the top surfaces of the source-side extension portion 22A and the drain-side extension portion 22B of the step layer 22 are directly covered by the second passivation layer 30 in the fourth embodiment.

(Manufacturing Method)

A manufacturing method of the nitride semiconductor apparatus 300 in FIG. 14 will be described.

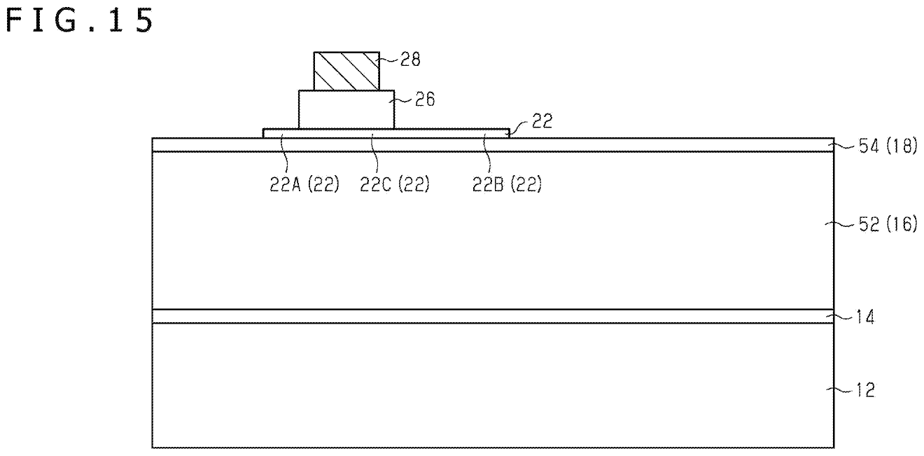

FIG. 15 is a schematic cross-sectional view illustrating an exemplary manufacturing process of the nitride semiconductor apparatus 300. Note that, in FIG. 15, some of the reference signs in FIG. 14 is indicated in parentheses for members including final constituent elements of the nitride semiconductor apparatus 300 or for members corresponding to the final constituent elements, in order to facilitate the understanding.

As illustrated in FIG. 15, the manufacturing method of the nitride semiconductor apparatus 300 includes removing the first dielectric layer 58. The first dielectric layer 58 corresponds to the first passivation layer 24. After the manufacturing process of the first embodiment illustrated in FIG. 8, the first passivation layer 24 formed on the step layer 22 is removed, and as a result, the top surfaces of the source-side extension portion 22A and the drain-side extension portion 22B of the step layer 22 are exposed.

In the first embodiment, the step layer 22 is covered by the second dielectric layer 64 through the first passivation layer 24 (see FIG. 9). In the fourth embodiment, the step layer 22 is directly covered by the second dielectric layer 64. The subsequent manufacturing process is similar to the process in FIG. 10, and the description will not be repeated.

An action of the nitride semiconductor apparatus 300 in the fourth embodiment different from the action of the nitride semiconductor apparatus 10 in the first embodiment will be described.

The nitride semiconductor apparatus 300 of the fourth embodiment does not include the first passivation layer 24 unlike in the first embodiment. This means that the distance between the source field plate portion 32B and the electron transit layer 16 is shorter than that in the case of the first embodiment. As a result, the source field plate portion 32B can more effectively extend the depletion layer to the region of the electron transit layer 16 just below the source field plate portion 32B compared to the first embodiment.

The fourth embodiment has the following effect in addition to the effects of the first embodiment.

(4-1) The nitride semiconductor apparatus 300 does not include the first passivation layer 24 on the step layer 22. Therefore, the depletion layer can be effectively extended from the source field plate portion 32B to the electron transit layer 16, and this can suppress the reduction in withstand voltage between the drain and the source of the nitride semiconductor apparatus 300 caused by the existence of the first passivation layer 24.

### Fifth Embodiment

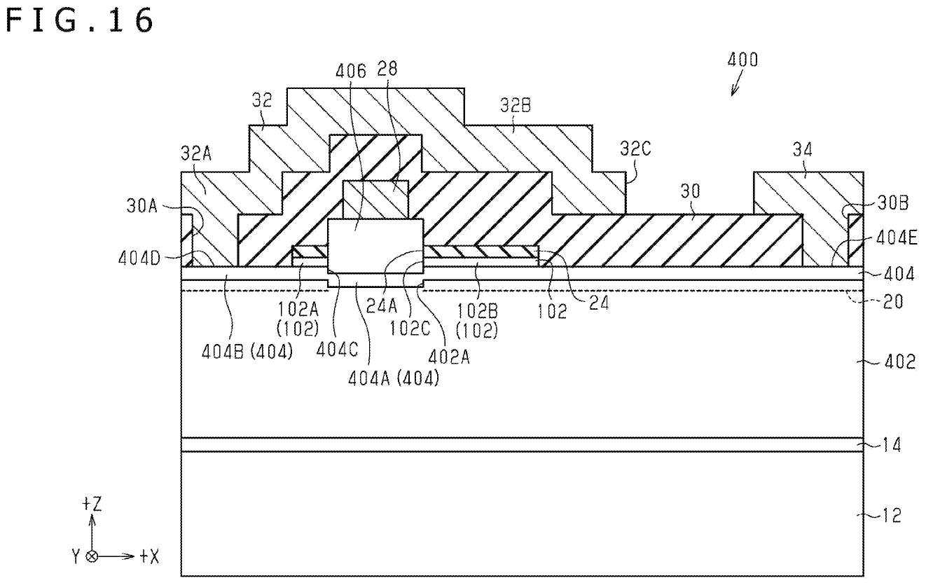

FIG. 16 is a schematic cross-sectional view of an exemplary nitride semiconductor apparatus 400 according to a fifth embodiment. In FIG. 16, the same reference signs as the reference signs in the second embodiment are provided to constituent elements similar to the constituent elements in the second embodiment, and the description will not be repeated.

The nitride semiconductor apparatus 400 of the fifth embodiment includes an electron transit layer 402; an electron supply layer 404 formed on the electron transit layer 402; and a gate layer 406 that is formed on part of the electron supply layer 404 and includes a nitride semiconductor containing acceptor impurities. The electron transit layer 402 includes a recess portion 402A having a depth smaller than the thickness of the electron supply layer 404, and the gate layer 406 is formed in the same region as the recess portion 402A in plan view. The fifth embodiment is different from the second embodiment in that the electron transit layer 402 includes the recess portion 402A formed on the top surface of the electron transit layer 402, and the electron supply layer 404 and the gate layer 406 are sequentially formed on the recess portion 402A.

The recess portion 402A is formed in the top surface of the electron transit layer 402 in the fifth embodiment. The recess portion 402A is formed in the same region as the opening portion 24A of the first passivation layer 24 and the opening portion 102C of the step layer 102 in plan view. The depth of the recess portion 402A can be equal to or greater than 2 nm and equal to or smaller than 12 nm. The depth of the recess portion 402A is smaller than the thickness of the electron supply layer 404. The configuration and the features of the electron transit layer 402 in the fifth embodiment can be similar to those of the electron transit layer 16 in the second embodiment except that the electron transit layer 402 includes the recess portion 402A.

The electron supply layer 404 includes a first part 404A on the recess portion 402A of the electron transit layer 402; and a second part 404B on the surface not provided with the recess portion 402A of the electron transit layer 402. The thickness of the first part 404A and the thickness of the second part 404B of the electron supply layer 404 can be, for example, equal to or greater than 5 nm and equal to or smaller than 15 nm. The thickness of the first part 404A may be the same as the thickness of the second part 404B or may be different. However, the value of the thickness of the first part 404A is larger than the value of the depth of the recess portion 402A of the electron transit layer 402 such that the first part 404A can be connected to the second part 404B to form a continuous layer. The value of the thickness of the first part 404A is smaller than the sum of the depth of the recess portion 402A of the electron transit layer 402 and the thickness of the second part 404B such that the electron supply layer 404 can include a recess portion 404C on the first part 404A. The opening portion 24A of the first passivation layer 24 communicates with the opening portion 102C of the step layer 102, and the opening portion 102C of the step layer 102 communicates with the recess portion 404C of the electron supply layer 404. The configuration and the features of the electron supply layer 404 in the fifth embodiment can be similar to those of the electron supply layer 18 in the second embodiment except that the electron supply layer 404 includes the first part 404A on the recess portion 402A of the electron transit layer 402. A source contact 404D and a drain contact 404E in FIG. 16 correspond to the source contact 18A and the drain contact 18B in FIG. 1, respectively.

The gate layer 406 is formed on the first part 404A of the electron supply layer 404. In other words, the electron supply layer 404 includes the first part 404A formed in the same region as the gate layer 406 in plan view; and the second part 404B formed in a region different from the gate layer 406 in plan view. The gate layer 406 is formed in the same region as the opening portion 24A of the first passivation layer 24, the opening portion 102C of the step layer 102, and the recess portion 404C of the electron supply layer 404 in plan view. Therefore, the gate layer 406 goes through the first passivation layer 24 and the step layer 102 and extends to the recess portion 404C of the electron supply layer 404. The configuration and the features of the gate layer 406 in the fifth embodiment can be similar to those of the gate layer 104 in the second embodiment except that the gate layer 406 extends to the recess portion 404C of the electron supply layer 404.

(Manufacturing Method)

A manufacturing method of the nitride semiconductor apparatus 400 in FIG. 16 will be described.

The manufacturing method of the nitride semiconductor apparatus 400 includes selectively etching through the third nitride semiconductor layer 56 and the second nitride semiconductor layer 54 to expose part of the first nitride semiconductor layer 52; etching the exposed first nitride semiconductor layer 52 to form a recess portion (corresponds to the recess portion 402A of the electron transit layer 402 in FIG. 16); re-growing the second nitride semiconductor layer 54 on the recess portion; and forming the fourth nitride semiconductor layer 60 on the re-grown second nitride semiconductor layer 54.

More specifically, the manufacturing method of the nitride semiconductor apparatus 400 includes forming an opening portion (not illustrated) going through the second nitride semiconductor layer 54 (corresponds to the electron supply layer 404 in FIG. 16) and a recess portion on the first nitride semiconductor layer 52 (corresponds to the recess portion 402A of the electron transit layer 402 in FIG. 16), in addition to the opening portion 56A going through the third nitride semiconductor layer 56 in the manufacturing process illustrated in FIG. 12.

The electron supply layer 404 and the gate layer 406 are then sequentially formed on the recess portion 402A of the electron transit layer 402. The electron supply layer 404 formed in this process corresponds to the first part 404A in FIG. 16. For example, the MOCVD method is used to epitaxially grow the first part 404A of the electron supply layer 404 that is an AlGaN layer and the gate layer 406 that is a p-type GaN layer in the fifth embodiment.

In the process described above, the second nitride semiconductor layer 54 is selectively etched and is then formed again on the recess portion 402A. Therefore, it can be stated that the second nitride semiconductor layer 54 is re-grown on the recess portion 402A. The re-grown second nitride semiconductor layer 54 corresponds to the first part 404A of the electron supply layer 404. The subsequent processes are similar to the processes in FIGS. 6 to 10, and the description will not be repeated.

An action of the nitride semiconductor apparatus 400 in the fifth embodiment different from the action of the nitride semiconductor apparatus 100 in the second embodiment will be described.

In the nitride semiconductor apparatus 400 of the fifth embodiment, the recess portion 402A is formed in the electron transit layer 402, and the first part 404A of the electron supply layer 404 is re-grown on the recess portion 402A unlike in the first embodiment. The gate layer 406 is formed on the first part 404A. In this way, the electron supply layer 404 (first part 404A) just below the gate layer 406 is a re-grown layer, and therefore, the growth conditions of the first part 404A can be different from the growth conditions of the second part 404B of the electron supply layer 404. For example, growth conditions that realize the reduction in on-resistance of the nitride semiconductor apparatus 400 can be selected for the growth of the second part 404B, and growth conditions that realize the normally-off operation of the nitride semiconductor apparatus 400 can be selected for the re-growth of the first part 404A. Different growth conditions can be used to, for example, form the first part 404A of the electron supply layer 404 from AlGaN with a composition different from that of the second part 404B or to make the thickness of the first part 404A different. For example, the first part 404A of the electron supply layer 404 may be formed from AlGaN with a thickness and a composition different from those of the second part 404B.

The fifth embodiment has the following effect in addition to the effects of the second embodiment.

(5-1) The electron transit layer 402 includes the recess portion 402A, and the first part 404A of the electron supply layer 404 is re-grown on the recess portion 402A. The gate layer 406 is formed on the first part 404A. According to this configuration, the first part 404A of the electron supply layer 404 just below the gate layer 406 is a re-grown layer, and thus, the growth conditions of the first part 404A can be different from the crystal growth conditions of the second part 404B of the electron supply layer 404. Therefore, the growth conditions of the electron supply layer 404 can be selected for the purpose of reducing the on-resistance in the region (second part 404B) other than the region just below the gate layer 406, while the growth conditions of the electron supply layer 404 for realizing a sufficiently high threshold voltage can be separately selected in the region (first part 404A) just below the gate layer 406.

### Sixth Embodiment

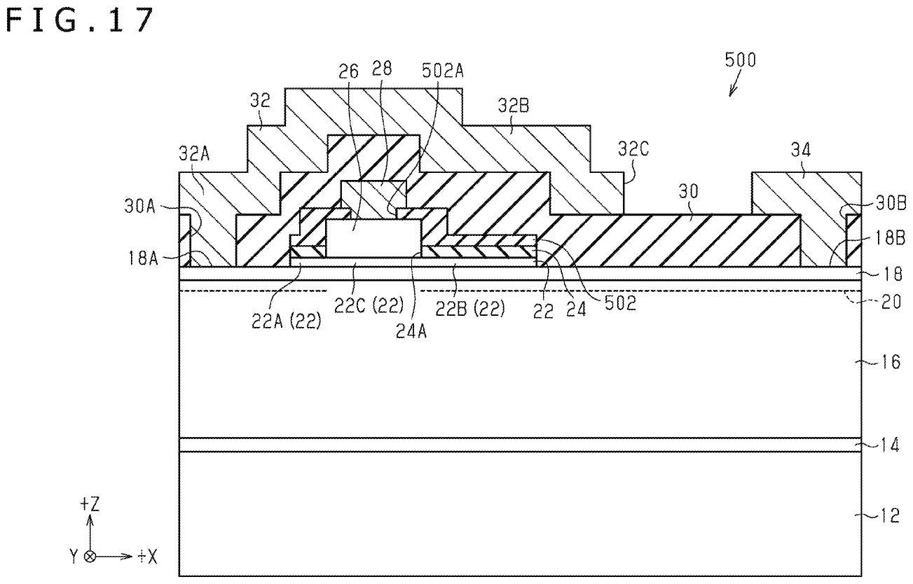

FIG. 17 is a schematic cross-sectional view of an exemplary nitride semiconductor apparatus 500 according to a sixth embodiment. In FIG. 17, the same reference signs as the reference signs in the first embodiment are provided to constituent elements similar to the constituent elements in the first embodiment, and the description will not be repeated.

The nitride semiconductor apparatus 500 of the sixth embodiment includes a third passivation layer 502 formed to cover the top surface of the first passivation layer 24, part of the top surface of the gate layer 26, and both side surfaces of the gate layer 26. The sixth embodiment is different from the first embodiment in that the third passivation layer 502 is included.

The third passivation layer 502 can be formed from, for example, an SiO₂ layer or an SiN layer. The third passivation layer 502 is an SiN layer in the sixth embodiment. The third passivation layer 502 includes an opening portion 502A that exposes part of the top surface of the gate layer 26. The gate electrode 28 formed on the gate layer 26 goes through the opening portion 502A and comes into contact with the top surface of the gate layer 26. The gate electrode 28 is also formed on part of the third passivation layer 502 covering the top surface of the gate layer 26. The thickness of the third passivation layer 502 covering the top surface of the first passivation layer 24 can be, for example, equal to or greater than 20 nm and equal to or smaller than 120 nm. In the sixth embodiment, the thickness of the third passivation layer 502 covering the top surface of the first passivation layer 24 is approximately 50 nm.

(Manufacturing Method)

A manufacturing method of the nitride semiconductor apparatus 500 in FIG. 17 will be described.

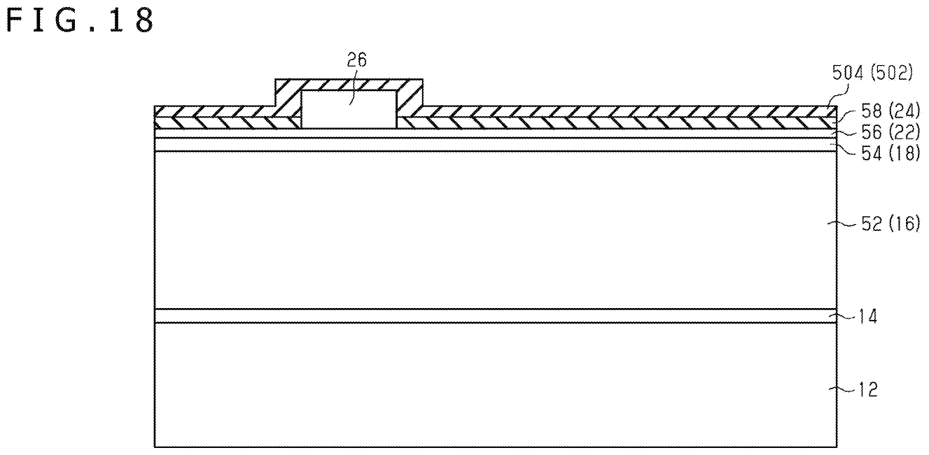

FIGS. 18 to 24 are schematic cross-sectional views illustrating exemplary manufacturing processes of the nitride semiconductor apparatus 500. Note that, in FIGS. 18 to 24, part of the reference signs in FIG. 17 is indicated in parentheses for members including final constituent elements of the nitride semiconductor apparatus 500 or for members corresponding to the final constituent elements, in order to facilitate the understanding.

The manufacturing method of the nitride semiconductor apparatus 500 in the sixth embodiment includes the manufacturing processes illustrated in FIGS. 3 to 5 common to the first embodiment and manufacturing processes illustrated in FIGS. 18 to 24 following the manufacturing processes illustrated in FIGS. 3 to 5.

FIG. 18 is a schematic cross-sectional view illustrating a manufacturing process following FIG. 5. As illustrated in FIG. 18, the manufacturing method of the nitride semiconductor apparatus 500 includes forming a third dielectric layer 504 so as to cover the entire exposed surfaces of the gate layer 26 and the first dielectric layer 58. For example, an SiN layer is formed as the third dielectric layer 504 in the sixth embodiment, and the SiN layer covers the exposed surfaces of the gate layer 26 and the first dielectric layer 58.

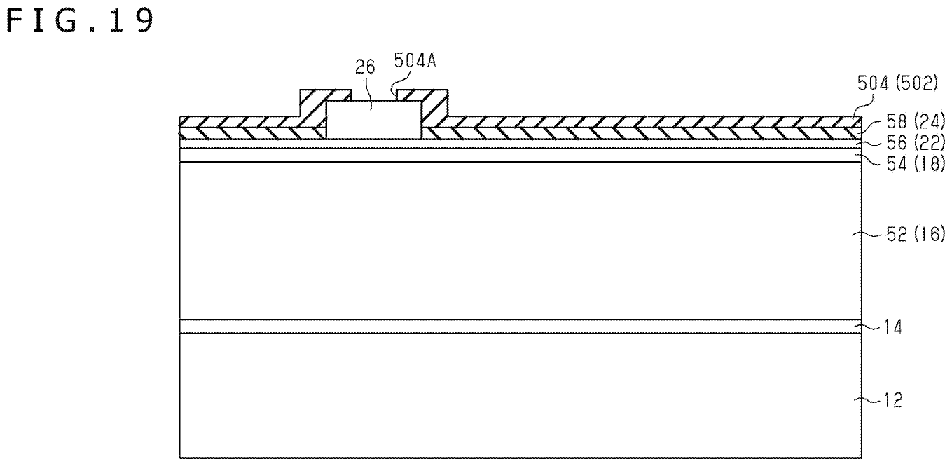

FIG. 19 is a schematic cross-sectional view illustrating a manufacturing process following FIG. 18. As illustrated in FIG. 19, the manufacturing method of the nitride semiconductor apparatus 500 includes selectively removing the third dielectric layer 504 to form an opening portion 504A going through the third dielectric layer 504 on the gate layer 26. The width of the opening portion 504A is smaller than the width of the gate layer 26. Therefore, the third dielectric layer 504 covers part of the side wall of the gate layer 26 and part of the top surface of the gate layer 26.

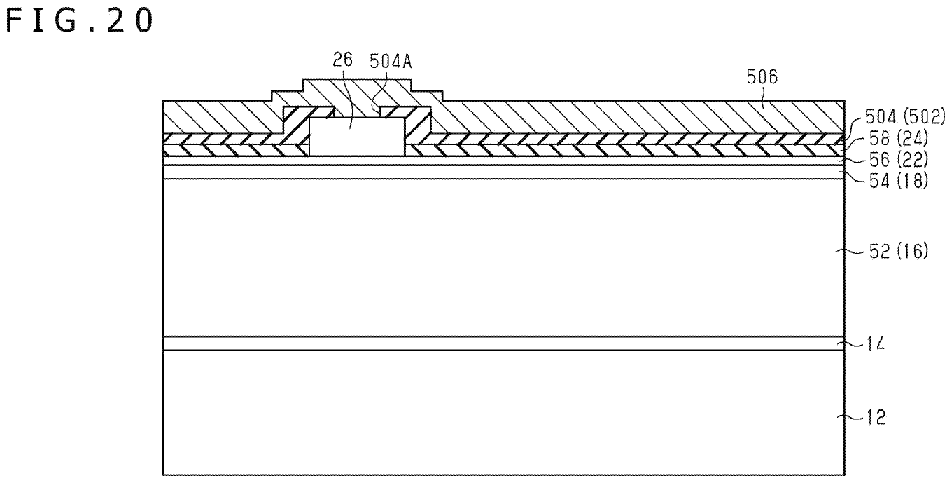

FIG. 20 is a schematic cross-sectional view illustrating a manufacturing process following FIG. 19. As illustrated in FIG. 20, the manufacturing method of the nitride semiconductor apparatus 500 includes forming a metal layer 506 so as to cover the entire exposed surfaces of the gate layer 26 and the third dielectric layer 504. In the sixth embodiment, the sputtering method is used to form, for example, a TiN layer as the metal layer 506, and the TiN layer covers the exposed surfaces of the gate layer 26 and the third dielectric layer 504.

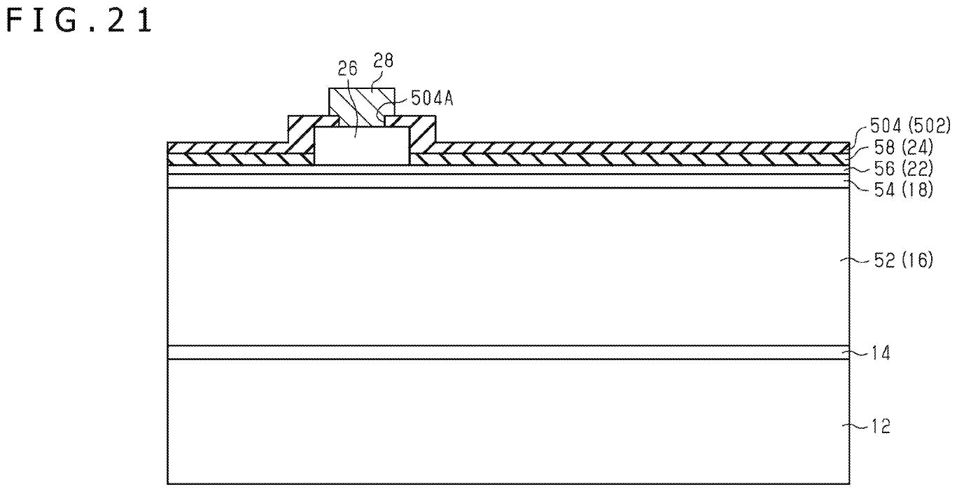

FIG. 21 is a schematic cross-sectional view illustrating a manufacturing process following FIG. 20. As illustrated in FIG. 21, the manufacturing method of the nitride semiconductor apparatus 500 includes selectively removing the metal layer 506 to form the gate electrode 28 on the gate layer 26. In this case, the side wall of the gate layer 26 is covered by the third dielectric layer 504, and the gate layer 26 is thus protected from process damage.

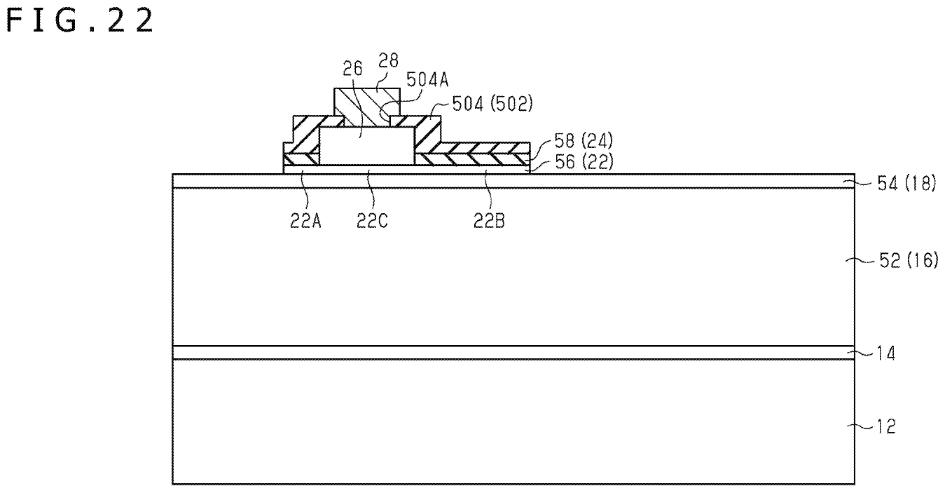

FIG. 22 is a schematic cross-sectional view illustrating a manufacturing process following FIG. 21. As illustrated in FIG. 22, the manufacturing method of the nitride semiconductor apparatus 500 includes selectively removing the third dielectric layer 504, the first dielectric layer 58, and the third nitride semiconductor layer 56. As a result, the third passivation layer 502, the first passivation layer 24, and the step layer 22 of FIG. 17 are formed.

For example, a mask is formed in the region corresponding to the step layer 22, and the mask is used to perform etching (for example, dry etching with at least one of Cl₂, SiCl₄, CF₄, and O₂) to sequentially pattern the third dielectric layer 504, the first dielectric layer 58, and the third nitride semiconductor layer 56. The mask is then stripped. The etching process of the third dielectric layer 504, the first dielectric layer 58, and the third nitride semiconductor layer 56 may include a plurality of etching processes as in the first embodiment.

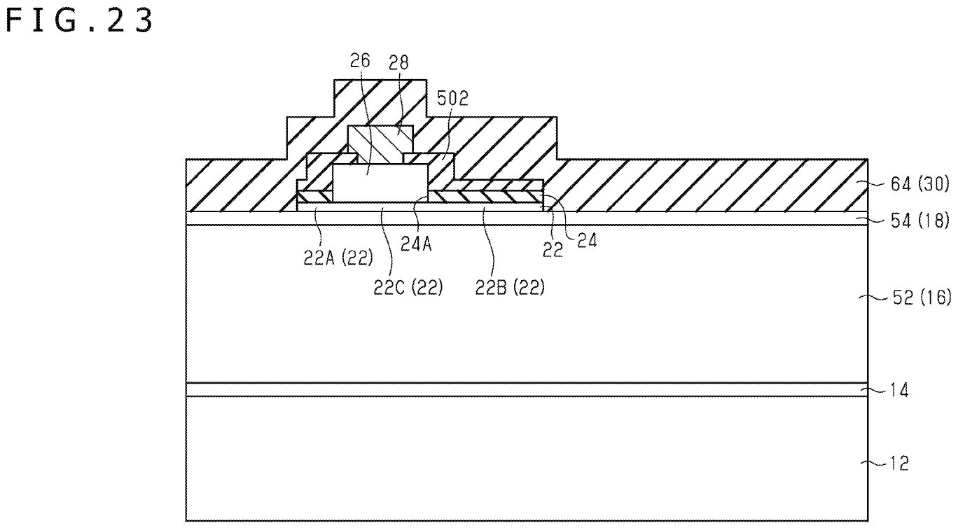

FIG. 23 is a schematic cross-sectional view illustrating a manufacturing process following FIG. 22. As illustrated in FIG. 23, the manufacturing method of the nitride semiconductor apparatus 500 includes forming the second dielectric layer 64. As a result, the second dielectric layer 64 is formed to cover the entire exposed surfaces of the step layer 22, the first passivation layer 24, the third passivation layer 502, the gate electrode 28, and the second nitride semiconductor layer 54. The second dielectric layer 64 of the sixth embodiment is formed by, for example, the LPCVD method as in the first embodiment. The second dielectric layer 64 corresponds to the second passivation layer 30 in FIG. 17.

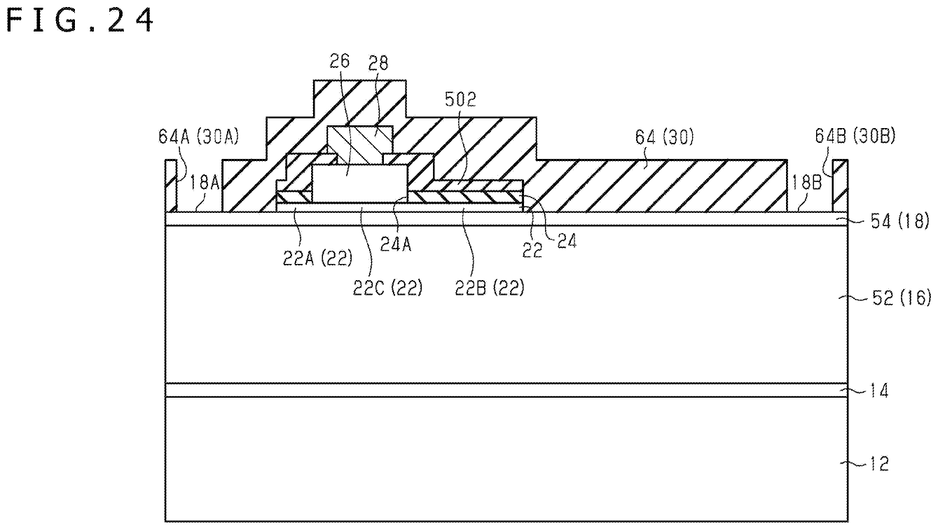

FIG. 24 is a schematic cross-sectional view illustrating a manufacturing process following FIG. 23. The manufacturing method of the nitride semiconductor apparatus 500 includes forming the source electrode 32 and the drain electrode 34 in contact with the second nitride semiconductor layer 54. The electrode formation process includes forming the contact holes 64A and 64B going through the second dielectric layer 64 as illustrated in FIG. 24. The second dielectric layer 64, the contact hole 64A, and the contact hole 64B correspond to the second passivation layer 30, the source contact hole 30A, and the drain contact hole 30B of FIG. 17, respectively. The electrode formation process further includes forming a metal layer filling the contact holes 64A and 64B and covering the entire exposed surface of the second dielectric layer 64; and pattering the metal layer by lithography and etching. As a result, the source electrode 32 and the drain electrode 34 of FIG. 17 are formed. The nitride semiconductor apparatus 500 of FIG. 17 is obtained by the processes described above.

An action of the nitride semiconductor apparatus 500 in the sixth embodiment different from the action of the nitride semiconductor apparatus 10 in the first embodiment will be described.

When the side wall of the gate layer 26 is not protected, etching damage may occur in the side wall of the gate layer 26, and the leakage current between the gate and the source may increase.

In this regard, the third passivation layer 502 covering the side wall of the gate layer 26 is formed in the nitride semiconductor apparatus 500 of the sixth embodiment, unlike in the first embodiment. This can reduce the process damage of the gate layer 26.

The sixth embodiment has the following effect in addition to the effects of the first embodiment.

(6-1) The third passivation layer 502 covering the side wall of the gate layer 26 is formed in the manufacturing method of the nitride semiconductor apparatus 500. According to this configuration, the side surface of the gate layer 26 can be protected in the manufacturing process of the gate electrode 28, and this can suppress the increase in leakage current between the gate and the source of the nitride semiconductor apparatus 500.

### Seventh Embodiment

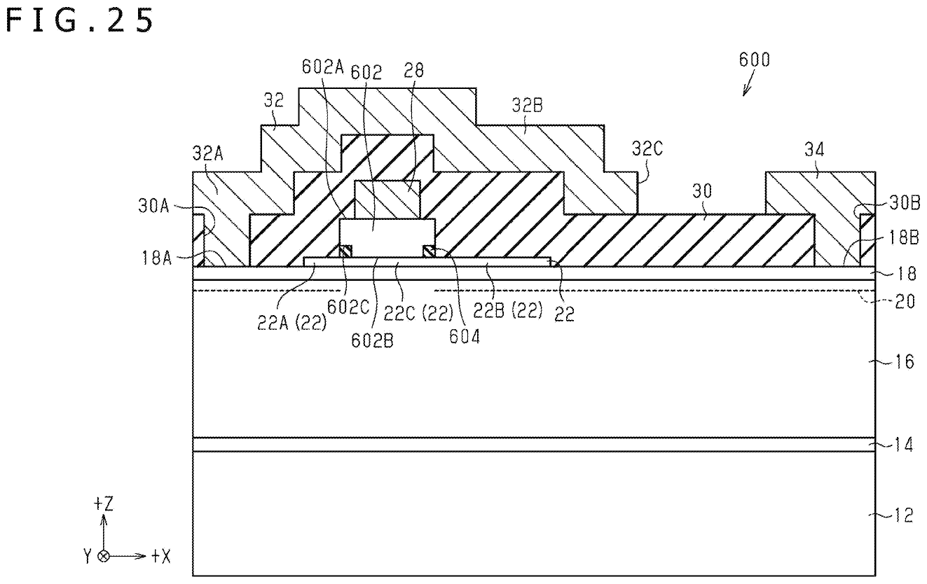

FIG. 25 is a schematic cross-sectional view of an exemplary nitride semiconductor apparatus 600 according to a seventh embodiment. In FIG. 25, the same reference signs as the reference signs in the first embodiment are provided to constituent elements similar to the constituent elements in the first embodiment, and the description will not be repeated.

The nitride semiconductor apparatus 600 of the seventh embodiment includes a gate layer 602 and a mask portion 604. The gate layer 602 includes a top surface 602A on which the gate electrode 28 is formed; a bottom surface 602B on the opposite side of the top surface 602A; and a side surface extending between the top surface 602A and the bottom surface 602B. A step 602C recessed from the side surface is formed on the end portion of the bottom surface 602B. The mask portion 604 is formed on the step 602C. More specifically, the mask portion 604 is arranged to fill the space generated by the recess of the step 602C. The mask portion 604 includes a nitride semiconductor with a composition different from those of the electron supply layer 18 and the step layer 22. The nitride semiconductor apparatus 600 of the seventh embodiment is different from the nitride semiconductor apparatus 10 of the first embodiment in that the nitride semiconductor apparatus 600 does not include the first passivation layer 24 and includes the mask portion 604 formed at a part between the step layer 22 and the gate layer 602.

The bottom surface 602B of the gate layer 602 is in contact with the step layer 22. The configuration and the features of the gate layer 602 in the seventh embodiment can be similar to those of the gate layer 26 in the first embodiment except that the gate layer 602 includes the step 602C.

The mask portion 604 includes a nitride semiconductor with a composition different from those of the electron supply layer 18 and the step layer 22. The mask portion 604 contains a relatively higher proportion of Al than those of the electron supply layer 18 and the step layer 22. For example, when the electron supply layer 18 is formed from AlₓGa₁₋ₓN, the mask portion 604 is formed from Al_{y}Ga_{1-y}N, where x≤y≤1. The mask portion 604 is an AlN layer in the seventh embodiment. The mask portion 604 is formed on the step 602C of the gate layer 602, and the thickness of the mask portion 604 is the same as the height of the step 602C. The thickness of the mask portion 604 can be, for example, equal to or greater than 0.5 nm and equal to or smaller than 10 nm. The thickness of the mask portion 604 can be set from the viewpoint of preventing a crack caused by film stress, and the thickness is approximately 1 nm in the seventh embodiment. The width of the mask portion 604 is, for example, approximately 100 nm.

(Manufacturing Method)

A manufacturing method of the nitride semiconductor apparatus 600 in FIG. 25 will be described.

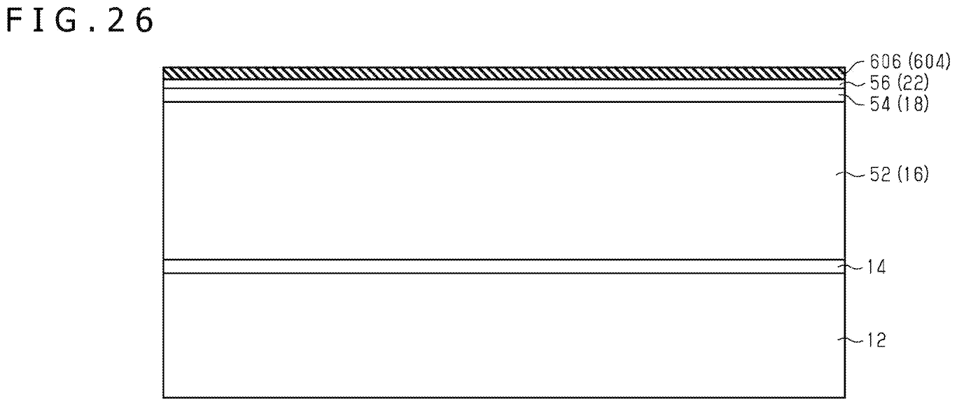

FIGS. 26 to 35 are schematic cross-sectional views illustrating exemplary manufacturing processes of the nitride semiconductor apparatus 600. Note that, in FIGS. 26 to 35, some of the reference signs in FIG. 25 is indicated in parentheses for members including final constituent elements of the nitride semiconductor apparatus 600 or for members corresponding to the final constituent elements, in order to facilitate the understanding.

As illustrated in FIG. 26, the buffer layer 14, the first nitride semiconductor layer 52, the second nitride semiconductor layer 54, the third nitride semiconductor layer 56, and a fifth nitride semiconductor layer 606 are sequentially formed on the substrate 12 that is, for example, an Si substrate. The MOCVD method can be used to epitaxially grow the buffer layer 14, the first nitride semiconductor layer 52, the second nitride semiconductor layer 54, the third nitride semiconductor layer 56, and the fifth nitride semiconductor layer 606. The configuration and the features of the buffer layer 14 in the seventh embodiment can be similar to those in the first embodiment.

The manufacturing method of the nitride semiconductor apparatus 600 includes forming the first nitride semiconductor layer 52; forming the second nitride semiconductor layer 54 on the first nitride semiconductor layer 52; forming the third nitride semiconductor layer 56 on the second nitride semiconductor layer 54; and forming the fifth nitride semiconductor layer 606 on the third nitride semiconductor layer 56. The configurations and the features of the first nitride semiconductor layer 52, the second nitride semiconductor layer 54, and the third nitride semiconductor layer 56 in the seventh embodiment can be similar to those in the first embodiment. In the seventh embodiment, an AlN layer is formed as the fifth nitride semiconductor layer 606 on a GaN layer formed as the third nitride semiconductor layer 56. The first nitride semiconductor layer 52 corresponds to the electron transit layer 16 of FIG. 25, and the second nitride semiconductor layer 54 corresponds to the electron supply layer 18 of FIG. 25.

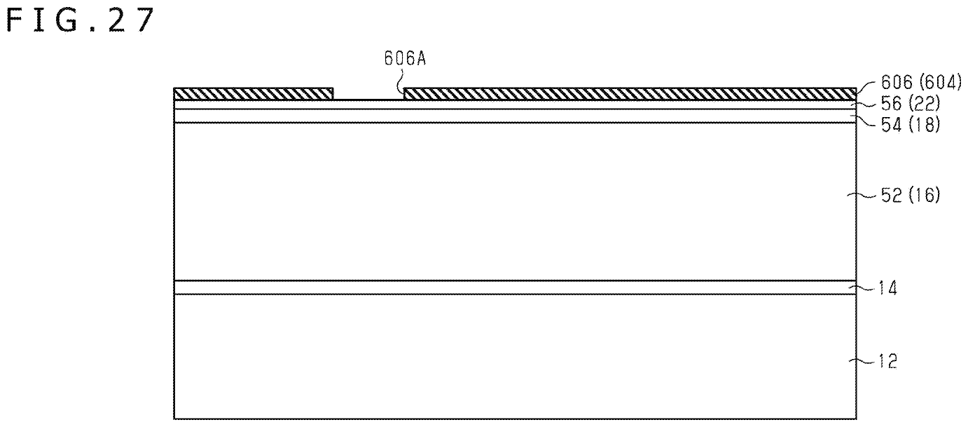

FIG. 27 is a schematic cross-sectional view illustrating a manufacturing process following FIG. 26. As illustrated in FIG. 27, the manufacturing method of the nitride semiconductor apparatus 600 includes forming an opening portion 606A on the fifth nitride semiconductor layer 606. For example, the fifth nitride semiconductor layer 606 is selectively removed by lithography and etching to form the opening portion 606A going through the fifth nitride semiconductor layer 606. As a result, part of the third nitride semiconductor layer 56 is exposed through the opening portion 606A. The width of the opening portion 606A corresponds to a gate width Lg of the nitride semiconductor apparatus 600. In the seventh embodiment, the width of the opening portion 606A can be equal to or greater than 0.4 μm and equal to or smaller than 1 μm.

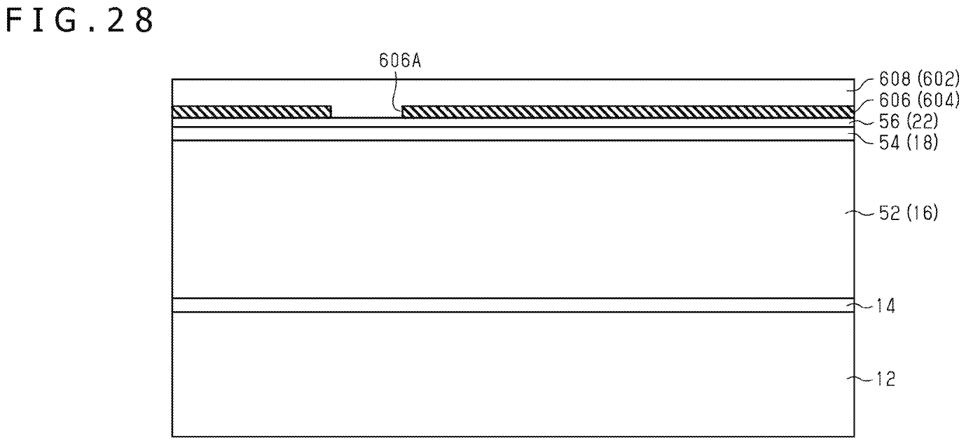

FIG. 28 is a schematic cross-sectional view illustrating a manufacturing method following FIG. 27. As illustrated in FIG. 28, the manufacturing method of the nitride semiconductor apparatus 600 includes forming a fourth nitride semiconductor layer 608. As a result, the fourth nitride semiconductor layer 608 is formed to cover the entire exposed surfaces of the third nitride semiconductor layer 56 and the fifth nitride semiconductor layer 606.

For example, the MOCVD method is used to epitaxially grow the fourth nitride semiconductor layer 608 that is a p-type GaN layer in the seventh embodiment. The lattice constant of the fifth nitride semiconductor layer 606 that is an AlN layer is relatively close to the lattice constant of the fourth nitride semiconductor layer 608 that is a p-type GaN layer. Therefore, the fourth nitride semiconductor layer 608 is epitaxially grown not only on the third nitride semiconductor layer 56, but also on the fifth nitride semiconductor layer 606.

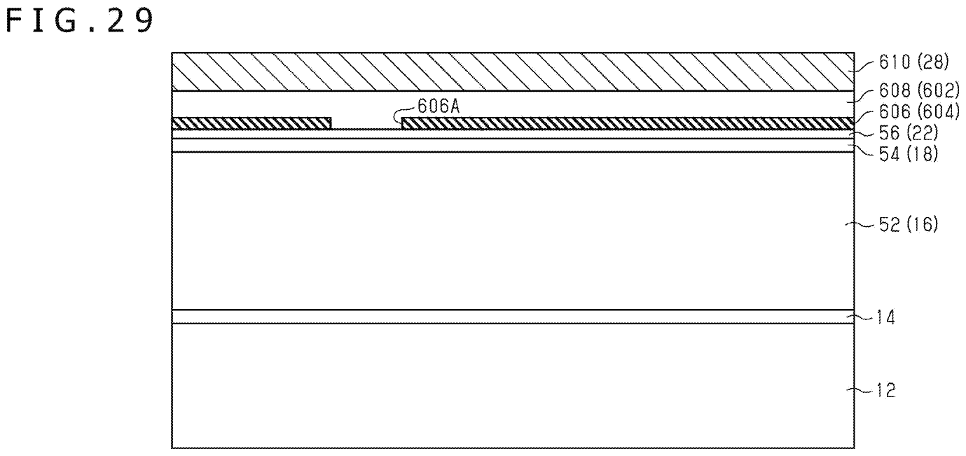

FIG. 29 is a schematic cross-sectional view illustrating a manufacturing process following FIG. 28. As illustrated in FIG. 29, the manufacturing method of the nitride semiconductor apparatus 600 includes forming a metal layer 610 on the fourth nitride semiconductor layer 608. In the seventh embodiment, the sputtering method is used to form, for example, a TiN layer as the metal layer 610.

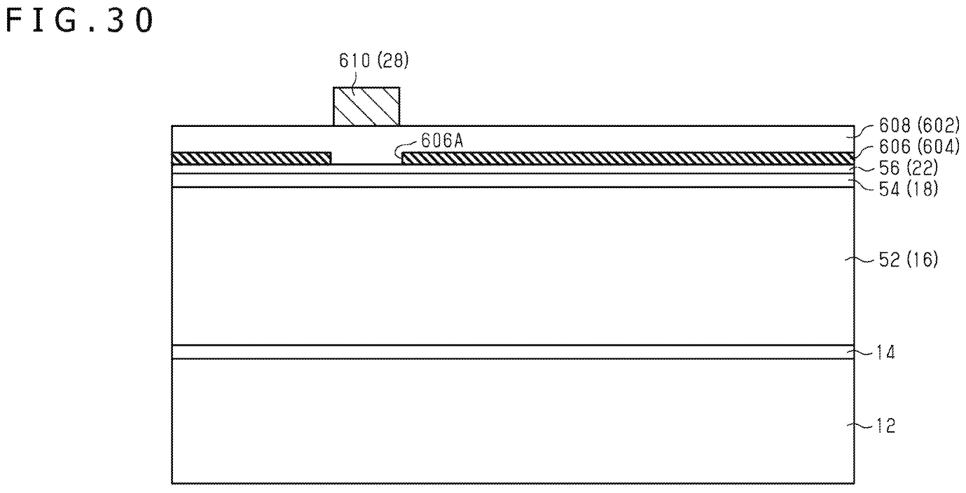

FIG. 30 is a schematic cross-sectional view illustrating a manufacturing process following FIG. 29. As illustrated in FIG. 30, the manufacturing method of the nitride semiconductor apparatus 600 includes selectively removing the metal layer 610 to form the gate electrode 28. The gate electrode 28 is formed in substantially the same region as the opening portion 606A of the fifth nitride semiconductor layer 606 in plan view.

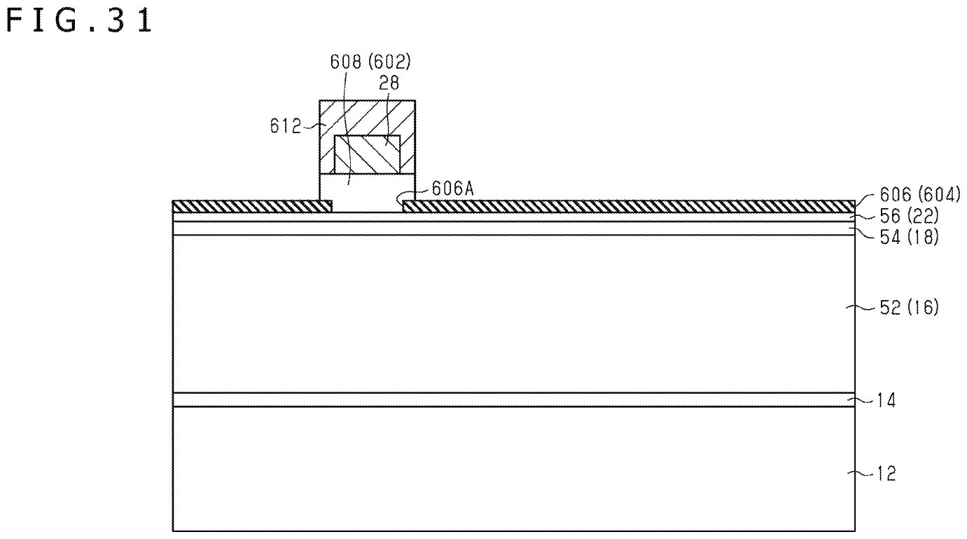

FIG. 31 is a schematic cross-sectional view illustrating a manufacturing process following FIG. 30. As illustrated in FIG. 31, the manufacturing method of the nitride semiconductor apparatus 600 includes using a mask 612 to selectively remove the fourth nitride semiconductor layer 608.

For example, the mask 612 is formed on the gate electrode 28 and on the fourth nitride semiconductor layer 608 around the gate electrode 28, and the mask 612 is used to etch the fourth nitride semiconductor layer 608 to form the gate layer 602. In this case, the fifth nitride semiconductor layer 606 functions as an etching stop layer. The mask 612 is formed to have a width larger than the width of the opening portion 606A of the fifth nitride semiconductor layer 606 to prevent a region without the fifth nitride semiconductor layer 606 that is the etching stop layer from being etched due to misalignment of lithography, etc. in forming the mask 612. For example, the margin of the lithography misalignment is approximately 100 nm.

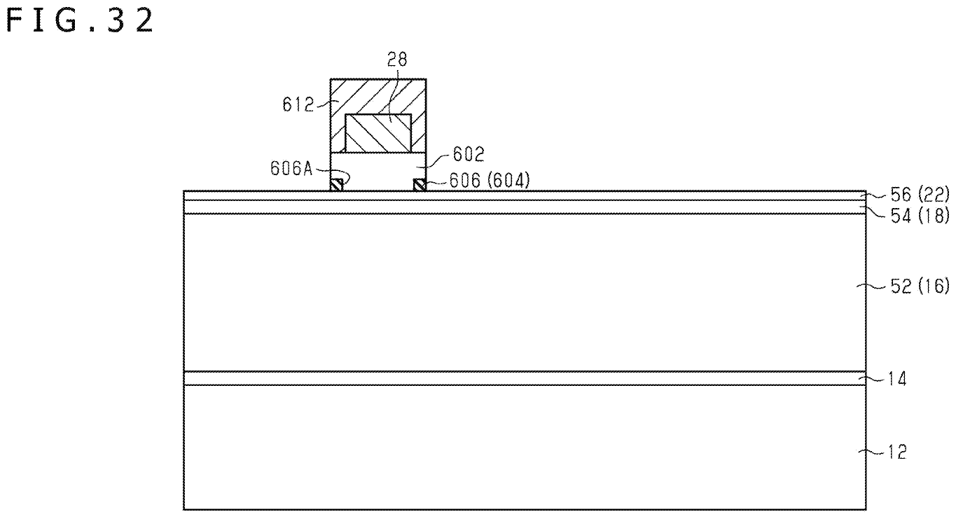

FIG. 32 is a schematic cross-sectional view illustrating a manufacturing process following FIG. 31. As illustrated in FIG. 32, the manufacturing method of the nitride semiconductor apparatus 600 includes using the mask 612 to selectively remove the fifth nitride semiconductor layer 606. The fifth nitride semiconductor layer 606 that is an AlN layer can be removed by, for example, wet etching with potassium hydroxide (KOH). However, the method of removing the fifth nitride semiconductor layer 606 is not limited to the wet etching, and other methods, such as dry etching, can also be used according to the configuration of the fifth nitride semiconductor layer 606. As a result, the surface of the third nitride semiconductor layer 56 is exposed in the region not covered by the mask 612 in plan view. On the other hand, part of the fifth nitride semiconductor layer 606 remains in the region covered by the mask 612 in plan view, and the remained part corresponds to the mask portion 604 of FIG. 25.

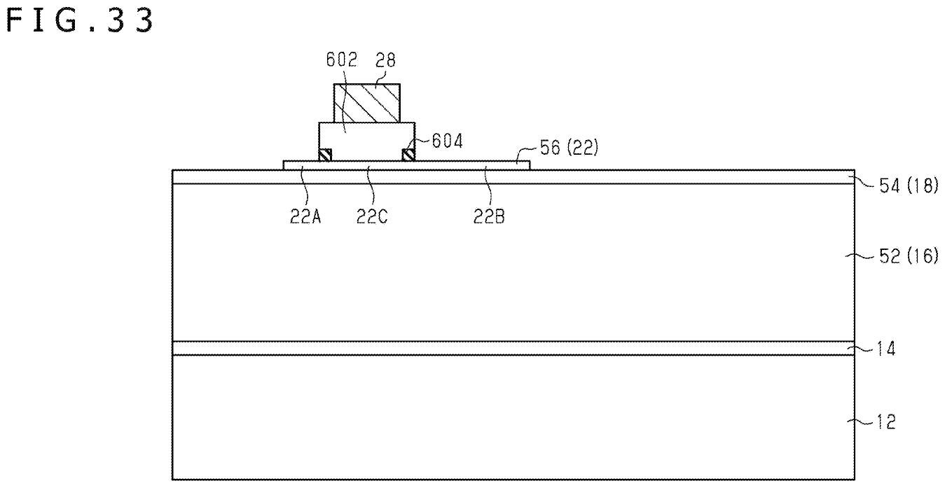

FIG. 33 is a schematic cross-sectional view illustrating a manufacturing process following FIG. 32. As illustrated in FIG. 33, the manufacturing method of the nitride semiconductor apparatus 600 includes selectively removing the third nitride semiconductor layer 56 to form the step layer 22.

After the mask 612 is stripped, a mask (not illustrated) is formed in the region corresponding to the step layer 22, and the mask is used to perform etching (for example, dry etching with at least one of Cl₂, SiCl₄, CF₄, and O₂) to pattern the third nitride semiconductor layer 56. Subsequently, a stripper or the like is used to strip the mask.

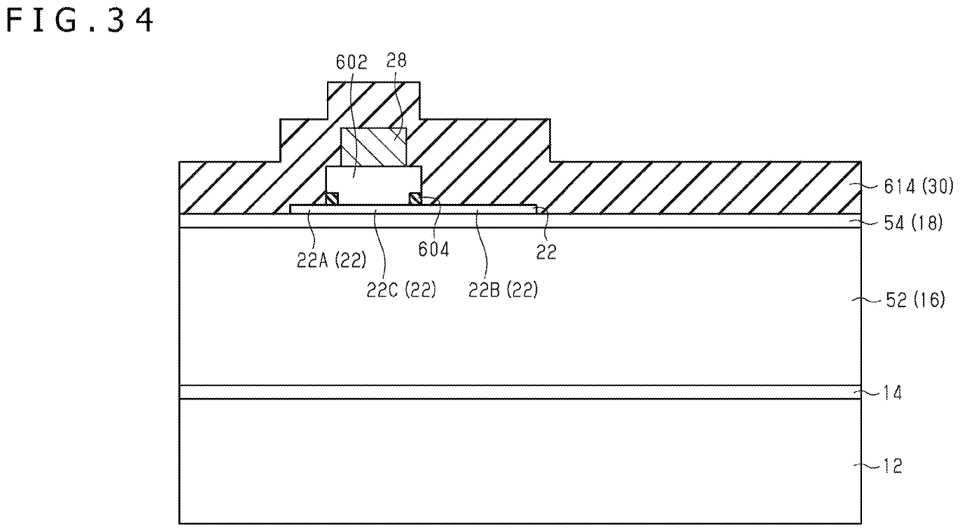

FIG. 34 is a schematic cross-sectional view illustrating a manufacturing process following FIG. 33. As illustrated in FIG. 34, the manufacturing method of the nitride semiconductor apparatus 600 includes forming a second dielectric layer 614. The second dielectric layer 614 is formed to cover the entire exposed surfaces of the step layer 22, the mask portion 604, the gate layer 602, the gate electrode 28, and the second nitride semiconductor layer 54. The configuration and the features of the second dielectric layer 614 in the seventh embodiment can be similar to those of the second dielectric layer 64 in the first embodiment. The second dielectric layer 614 corresponds to the second passivation layer 30 of FIG. 25.

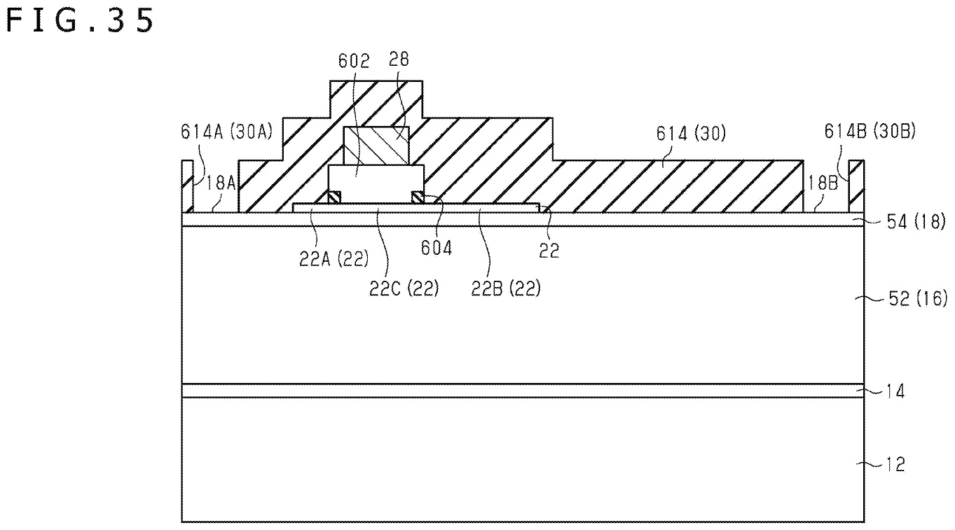

FIG. 35 is a schematic cross-sectional view illustrating a manufacturing process following FIG. 34. The manufacturing method of the nitride semiconductor apparatus 600 includes forming the source electrode 32 and the drain electrode 34 in contact with the second nitride semiconductor layer 54. The electrode formation process includes forming contact holes 614A and 614B going through the second dielectric layer 614 as illustrated in FIG. 35. The second dielectric layer 614, the contact hole 614A, and the contact hole 614B correspond to the second passivation layer 30, the source contact hole 30A, and the drain contact hole 30B of FIG. 25, respectively. The electrode formation process further includes filling the contact holes 64A and 64B to form a metal layer covering the entire exposed surface of the second dielectric layer 64; and pattering the metal layer by lithography and etching. As a result, the source electrode 32 and the drain electrode 34 of FIG. 25 are formed. The nitride semiconductor apparatus 600 of FIG. 25 is obtained by the processes described above.

An action of the nitride semiconductor apparatus 600 in the seventh embodiment different from the action of the nitride semiconductor apparatus 10 in the first embodiment will be described.

In the nitride semiconductor apparatus 600 of the seventh embodiment, the MOCVD method is used to continuously and epitaxially grow the fifth nitride semiconductor layer 606 on the third nitride semiconductor layer 56 unlike in the first embodiment. This can suppress the process damage of the third nitride semiconductor layer 56 more than in the case of using the plasm CVD method to form a film on the third nitride semiconductor layer 56 as in the first embodiment, and as a result, the step layer 22 with less damage can be obtained.

In addition, the fifth nitride semiconductor layer 606 that is an AlN layer can be removed by wet etching with KOH, and this can suppress damaging the gate layer 602 more than in the case of using dry etching.

The seventh embodiment has the following effect in addition to the effects of the first embodiment.

(7-1) In the manufacturing method of the nitride semiconductor apparatus 600, the fifth nitride semiconductor layer 606 is formed on the third nitride semiconductor layer 56 corresponding to the step layer 22. This can reduce the process damage of the step layer 22, and as a result, a stable normally-off HEMT can be obtained.

### Eighth Embodiment

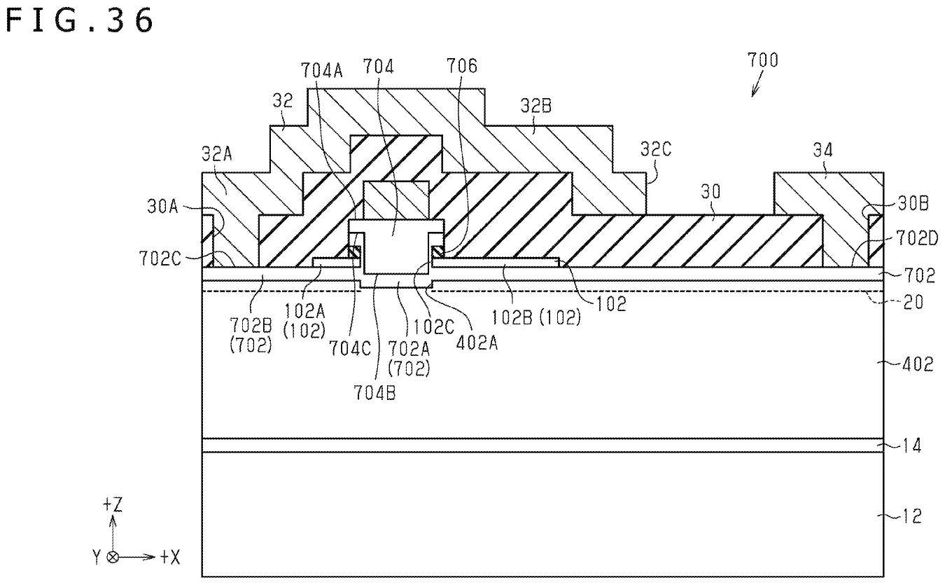

FIG. 36 is a schematic cross-sectional view of an exemplary nitride semiconductor apparatus 700 according to an eighth embodiment. In FIG. 36, the same reference signs as the reference signs in the fifth embodiment are provided to constituent elements similar to the constituent elements in the fifth embodiment, and the description will not be repeated.

The nitride semiconductor apparatus 700 of the eighth embodiment includes an electron supply layer 702, a gate layer 704, and a mask portion 706. The nitride semiconductor apparatus 700 of the eighth embodiment is different from the nitride semiconductor apparatus 400 of the fifth embodiment in that the nitride semiconductor apparatus 700 does not include the first passivation layer 24 and includes the mask portion 706 formed on part of the step layer 22, and that the electron supply layer 702 extends from the recess portion 402A of the electron transit layer 402 to the top surface of the mask portion 706.

The electron supply layer 702 includes a first part 702A extending from the recess portion 402A of the electron transit layer 402 to the top surface of the mask portion 706; and a second part 702B on the surface not provided with the recess portion 402A of the electron transit layer 402. The configuration and the features of the electron supply layer 702 in the eighth embodiment can be similar to those of the electron supply layer 18 in the first embodiment except that the electron supply layer 702 includes the first part 702A extending from the recess portion 402A of the electron transit layer 402 to the top surface of the mask portion 706. A source contact 702C and a drain contact 702D of FIG. 36 correspond to the source contact 18A and the drain contact 18B of FIG. 1, respectively.

The gate layer 704 includes a top surface 704A on which the gate electrode 28 is formed; a bottom surface 704B on the opposite side of the top surface 704A; and a side surface extending between the top surface 704A and the bottom surface 704B. A step 704C recessed from the side surface is formed on the end portion of the bottom surface 704B. The bottom surface 704B of the gate layer 704 is in contact with the first part 702A of the electron supply layer 702. Part of the first part 702A of the electron supply layer 702, the mask portion 706, part of the step layer 102, and part of the second part 702B of the electron supply layer 702 are arranged to fill the space generated by the recess of the step 704C. More specifically, part of the first part 702A is arranged to fill the space formed between the top surface of the mask portion 706 and the step 704C. The configuration and the features of the gate layer 704 in the eight embodiment can be similar to those of the gate layer 26 in the first embodiment except that the gate layer 704 includes the step 704C.

The mask portion 706 is formed from a nitride semiconductor with a composition different from those of the electron supply layer 702 and the step layer 102. The mask portion 706 contains a relatively higher proportion of Al than the electron supply layer 702 and the step layer 102. For example, when the electron supply layer 702 is formed from AlₓGa₁₋ₓN, the mask portion 706 is formed from Al_{y}Ga_{1-y}N, where x≤y≤1. The mask portion 706 is an AlN layer in the eighth embodiment. The mask portion 706 is formed between the step layer 102 and the electron supply layer 702 formed on the step 704C of the gate layer 704. Therefore, the top surface and one side surface of the mask portion 706 are covered by the electron supply layer 702. The thickness of the mask portion 706 can be, for example, equal to or greater than 0.5 nm and equal to or smaller than 10 nm. The thickness of the mask portion 706 can be set from the viewpoint of preventing a crack caused by film stress, and the thickness is approximately 1 nm in the eighth embodiment.

(Manufacturing Method)

A manufacturing method of the nitride semiconductor apparatus 700 in FIG. 36 will be described.

The manufacturing method of the nitride semiconductor apparatus 700 in the eight embodiment includes forming an opening portion (corresponds to the opening portion 102C of FIG. 36) going through the third nitride semiconductor layer 56 (corresponds to the step layer 102 of FIG. 36), an opening portion (not illustrated) going through the second nitride semiconductor layer 54 (corresponds to the electron supply layer 702 of FIG. 36), and a recess portion (corresponds to the recess portion 402A of FIG. 36) on the first nitride semiconductor layer 52 (corresponds to the electron transit layer 402 of FIG. 36), in addition to the opening portion 606A going through the fifth nitride semiconductor layer 606 in the manufacturing process illustrated in FIG. 27. The opening portions and the recess portion communicate with each other to provide a groove (not illustrated).

The second nitride semiconductor layer 54 (corresponds to the electron supply layer 702) and the fourth nitride semiconductor layer 608 (corresponds to the gate layer 704) are then sequentially formed on the groove. The second nitride semiconductor layer 54 formed in this process corresponds to the first part 702A of the electron supply layer 702 in FIG. 36. For example, the MOCVD method is used to epitaxially grow the first part 702A of the electron supply layer 702 that is an AlGaN layer and the gate layer 704 that is a p-type GaN layer in the eighth embodiment. The subsequent processes are similar to the processes in FIGS. 30 to 35, and the description will not be repeated. Note that the part remained after the selective removal of the fifth nitride semiconductor layer 606 corresponds to the mask portion 706 of FIG. 36.

An action of the nitride semiconductor apparatus 700 in the eighth embodiment different from the action of the nitride semiconductor apparatus 400 in the fifth embodiment will be described.

In the nitride semiconductor apparatus 700 of the eighth embodiment, the MOCVD method is used to continuously and epitaxially grow the fifth nitride semiconductor layer 606 on the third nitride semiconductor layer 56, unlike in the fifth embodiment. This can suppress the process damage of the third nitride semiconductor layer 56 more than in the case of using the plasma CVD method to form the film on the third nitride semiconductor layer 56 as in the fifth embodiment, and as a result, the step layer 102 with less damage can be obtained.

In addition, the fifth nitride semiconductor layer 606 that is an AlN layer can be removed by wet etching with KOH, and this can suppress damaging the gate layer 704 more than in the case of using dry etching.

The eighth embodiment has the following effect in addition to the effects of the fifth embodiment.

(8-1) In the manufacturing method of the nitride semiconductor apparatus 700, the fifth nitride semiconductor layer 606 is formed on the third nitride semiconductor layer 56 corresponding to the step layer 102. This can reduce the process damage of the step layer 102, and as a result, a stable normally-off HEMT can be obtained.

(Example of Formation Pattern of Nitride Semiconductor Apparatus)

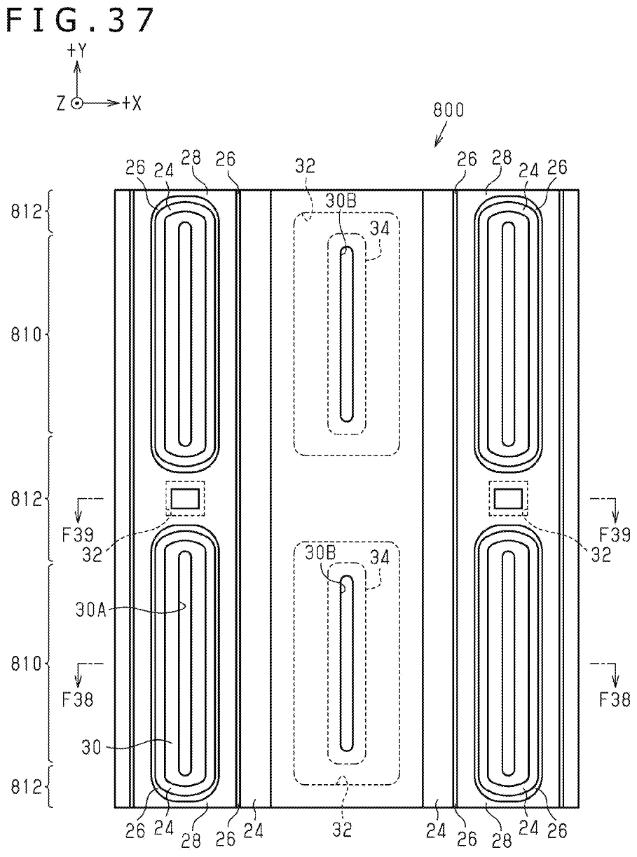

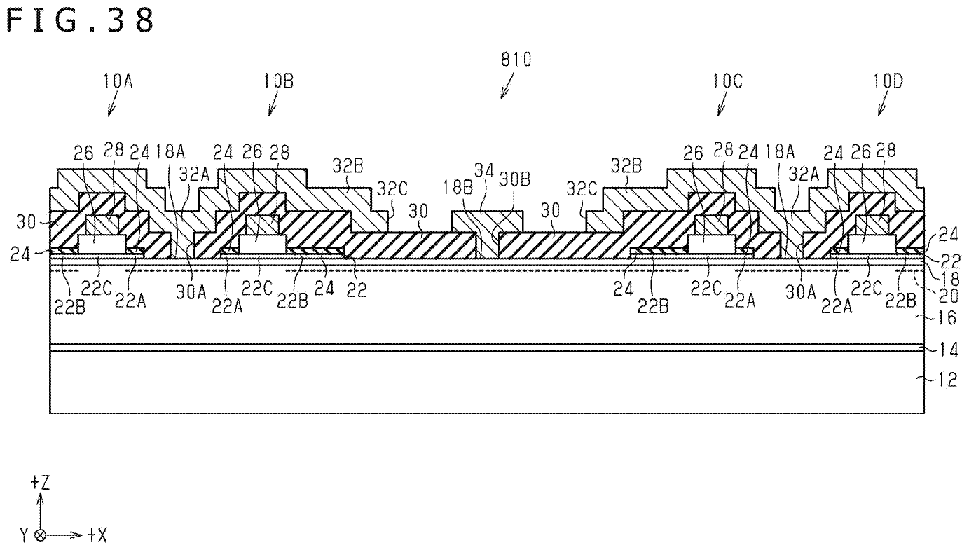

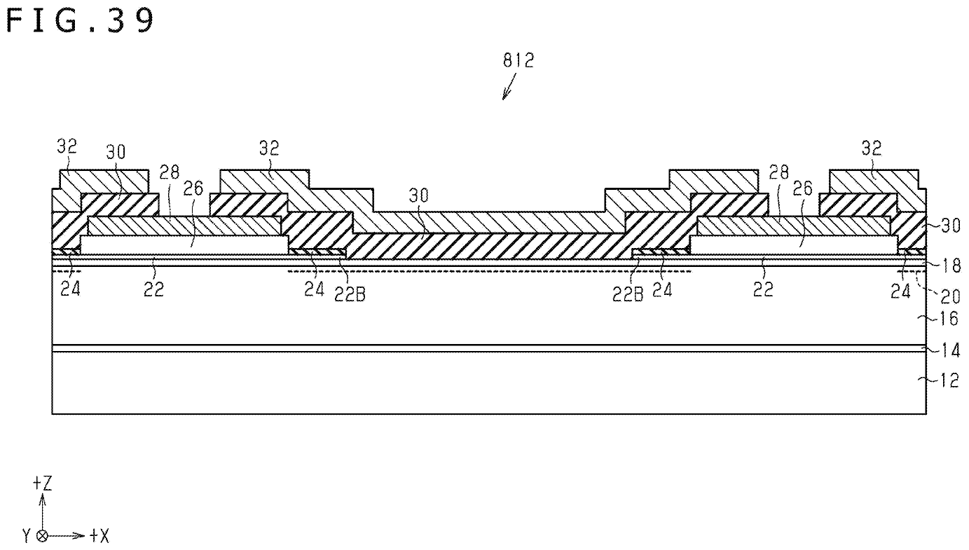

FIG. 37 is a schematic plan view illustrating an exemplary formation pattern 800 of the nitride semiconductor apparatus 10 in FIG. 1. FIG. 38 is a schematic cross-sectional view of an active region 810 along a line F38-F38 in FIG. 37, and FIG. 39 is a schematic cross-sectional view of an inactive region 812 along a line F39-F39 in FIG. 37. Note that, to facilitate the understanding, the same reference signs are provided to constituent elements in FIGS. 37 to 39 similar to the constituent elements in FIG. 1. The source electrodes 32 and the drain electrodes 34 are indicated by dashed lines in FIG. 37 to avoid complication of the illustration.

As illustrated in FIG. 37, the formation pattern 800 includes the active region 810 contributing to the transistor operation and the inactive region 812 not contributing to the transistor operation. The active region 810 represents a region in which the current flows between the source and the drain when the voltage is applied to the gate electrode 28.

As illustrated in FIG. 38, a plurality of (four in the example of FIG. 38) nitride semiconductor apparatuses (HEMTs) 10A to 10D are continuously formed in the X-axis direction in the active region 810. Note that the configuration of each of the nitride semiconductor apparatuses 10A to 10D is similar to the configuration of the nitride semiconductor apparatus 10 in FIG. 1.

In the example of FIG. 38, the nitride semiconductor apparatuses 10A and 10B are laid out such that the source-side extension portion 22A of the step layer 22 of the nitride semiconductor apparatus 10A faces the source-side extension portion 22A of the step layer 22 of the nitride semiconductor apparatus 10B through the source electrode portion 32A. The nitride semiconductor apparatuses 10C and 10D are also laid out in a similar arrangement relation. The nitride semiconductor apparatuses 10B and 10C are laid out such that the drain-side extension portion 22B of the step layer 22 of the nitride semiconductor apparatus 10B faces the drain-side extension portion 22B of the step layer 22 of the nitride semiconductor apparatus 10C through the drain electrode 34. On the other hand, as illustrated in FIG. 39, the drain electrode 34 is not formed in the inactive region 812, and the second passivation layer 30 and the source electrode 32 are continuously formed in the X-axis direction. As illustrated in FIG. 37, the first passivation layer 24, the gate layer 26, the gate electrode 28, and the source electrode 32 are continuously formed in the Y-axis direction in the active region 810 and the inactive region 812. Although not illustrated, the step layer 22 is also continuously formed in the active region 810 and the inactive region 812.

As illustrated in FIGS. 37 to 39, the step layer 22 and the first passivation layer 24 (the step layer 22 is not illustrated in FIG. 37) extend outside of the gate layer 26 in plan view. For example, the step layer 22 extends outside of the entire outer periphery of the gate layer 26 in plan view in each of the active region 810 and the inactive region 812. In other words, the step layer 22 extends outside of the gate layer 26 in every direction including the +X direction, the −X direction, the +Y direction, and the −Y direction in the XY plane. In this way, the area of the step layer 22 is larger than the area of the gate layer 26 in plan view, and therefore, the step layer 22 can disperse the holes not only in the X-axis direction, but also in the Y-axis direction. Note that the formation pattern 800 illustrated in FIG. 37 may be applied to the nitride semiconductor apparatuses 100, 200, 300, 400, 500, 600, and 700 of FIGS. 11, 13, 14, 16, 17, 25, and 36.

(Another Example of Formation Pattern of Nitride Semiconductor Apparatus)

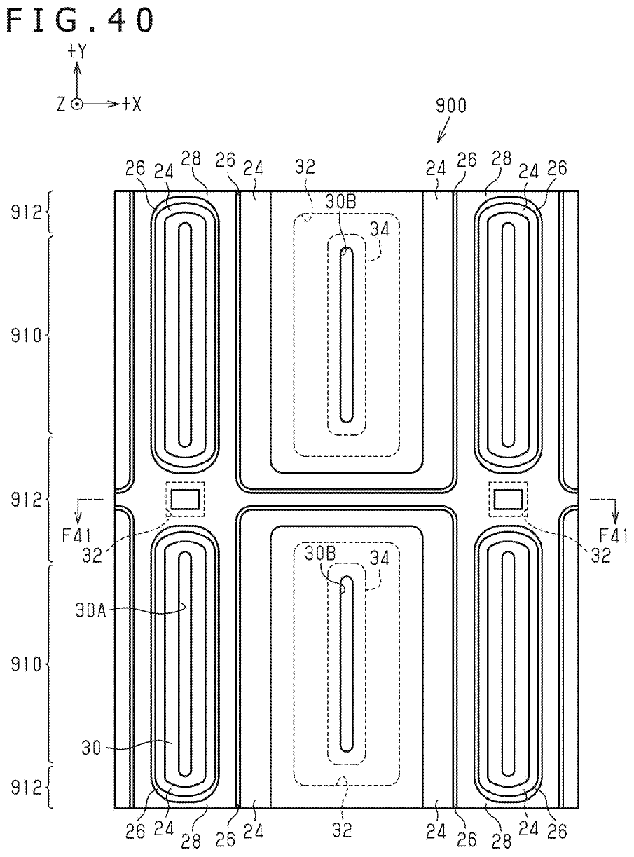

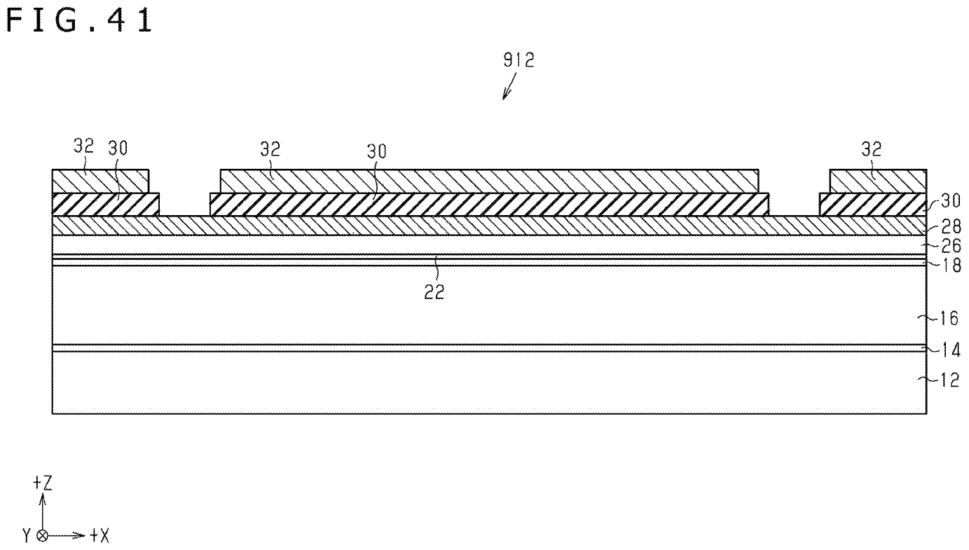

FIG. 40 is a schematic plan view illustrating another exemplary formation pattern 900 of the nitride semiconductor apparatus 10 in FIG. 1, and FIG. 41 is a schematic cross-sectional view of an inactive region 912 along a line F41-F41 in FIG. 40. Note that, to facilitate the understanding, the same reference signs are provided to constituent elements in FIGS. 40 and 41 similar to the constituent elements in FIG. 1. The source electrode 32 and the drain electrode 34 are indicated by dashed lines in FIG. 40 to avoid complication of the illustration.

As in the formation pattern 800 of FIG. 37, the formation pattern 900 includes an active region 910 and the inactive region 912. The layout of the nitride semiconductor apparatus 10 in the active region 910 is similar to the layout illustrated in FIG. 38.

As illustrated in FIGS. 40 and 41, the step layer 22 (the step layer 22 is not illustrated in FIG. 40), the first passivation layer 24 (the first passivation layer 24 is not illustrated in FIG. 41), the gate layer 26, the gate electrode 28, the second passivation layer 30, and the source electrode 32 are continuously formed in the X-axis direction in the inactive region 912. Therefore, in the inactive region 912, the GaN layer that is the step layer 22 continuously covers the AlGaN layer included in the electron supply layer 18 in the X-axis direction. In the inactive region 912, the SiO₂ layer that is the first passivation layer 24 continuously covers the step layer 22 (GaN layer) in the X-axis direction (the first passivation layer 24 is not illustrated in FIG. 41). The gate layer 26 continuously covers the step layer 22, and the gate electrode 28 continuously covers the gate layer 26.

In this way, the area of the step layer 22 formed in the inactive region 912 is larger in the formation pattern 900 than in the formation pattern 800 of FIG. 37 (see FIGS. 39 and 41). This can reduce the hole density in the interface between the step layer 22 and the electron supply layer more than in the case of using the formation pattern 800 of FIG. 37. As a result, the formation pattern 900 can be used to further reduce the gate leakage current to improve the gate withstand voltage. In addition, the area of the gate electrode 28 formed in the inactive region 912 is larger in the formation pattern 900 than in the formation pattern 800 of FIG. 37. This can reduce the gate wiring resistance. Note that the formation pattern 900 illustrated in FIG. 40 may be applied to the nitride semiconductor apparatuses 100, 200, 300, 400, 500, 600, and 700 of FIGS. 11, 13, 14, 16, 17, 25, and 36.

Note that, as in FIG. 37, the step layer 22 also extends outside of the entire outer periphery of the gate layer 26 in plan view in each of the active region 910 and the inactive region 912 in the example of FIG. 40. In this way, the area of the step layer 22 is larger than the area of the gate layer 26 in plan view, and therefore, the step layer 22 can disperse the holes not only in the X-axis direction, but also in the Y-axis direction.

### Change Example of Sixth Embodiment

The third passivation layer 502 may not cover the top surface of the first passivation layer 24. In this case, the third passivation layer 502 is formed to cover part of the top surface of the gate layer 26 and both side surfaces of the gate layer 26.

According to this configuration, the side surfaces of the gate layer 26 can be protected in the manufacturing process of the gate electrode 28, and this can thus suppress the increase in leakage current between the gate and the source of the nitride semiconductor apparatus 500.

### Change Example of Seventh Embodiment

An SiN layer may be used as the mask portion 604. The SiN layer can be formed by using, for example, the LPCVD method. The thickness of the SiN layer can be equal to or greater than 30 nm and equal to or smaller than 200 nm. In this change example, the thickness of the SiN layer is preferably 50 nm.

A manufacturing method of the nitride semiconductor apparatus in this change example will be described.

The MOCVD method is used to epitaxially grow the buffer layer 14, the first nitride semiconductor layer 52, the second nitride semiconductor layer 54, and the third nitride semiconductor layer 56 on the substrate 12 that is, for example, an Si substrate. Unlike in the seventh embodiment, the fifth nitride semiconductor layer 606 is not formed at this point. The LPCVD method is then used to form an SiN layer as the fifth nitride semiconductor layer 606 on the third nitride semiconductor layer 56. The subsequent processes are similar to the processes in FIGS. 27 to 35, and the description will not be repeated.

According to this configuration, the normally-on operation of the nitride semiconductor apparatus 600 just below the mask portion 604 can be prevented.

The word “on” used in the present disclosure includes meanings of “on” and “above” unless the context clearly indicates otherwise. Therefore, an expression “a first layer is formed on a second layer” is intended to indicate that the first layer can be in contact with the second layer and directly arranged on the second layer in one embodiment. In another embodiment, the expression is intended to indicate that the first layer can be arranged above the second layer without being in contact with the second layer. That is, the word “on” does not exclude a structure in which another layer is formed between the first layer and the second layer. For example, each of the embodiments including the electron supply layer 18 formed on the electron transit layer 16 also includes a structure including an intermediate layer positioned between the electron supply layer 18 and the electron transit layer 16 for stable formation of the 2DEG 20.

The Z-axis direction used in the present disclosure may not be the vertical direction and may not completely coincide with the vertical direction. Therefore, “up” and “down” in the Z-axis direction described in the present specification may not be “up” and “down” in the vertical direction in various structures according to the present disclosure (for example, the structure illustrated in FIG. 1). For example, the X-axis direction may be the vertical direction, or the Y-axis direction may be the vertical direction.

[Supplements]

Technical ideas that can be figured out from the embodiments and the change examples will be described below. Note that the corresponding reference signs in the embodiments are indicated in parentheses for the components described in the supplements to aid the understanding of the technical ideas, not to limit the technical ideas.

(Supplement A1)

A nitride semiconductor apparatus (10) including:

an electron transit layer (16) including a nitride semiconductor;

an electron supply layer (18) that is formed on the electron transit layer (16) and includes a nitride semiconductor with a band gap larger than a band gap of the electron transit layer (16);

a step layer (22) that is formed on part of the electron supply layer (18) and includes a nitride semiconductor with a band gap smaller than the band gap of the electron supply layer (18);

a gate layer (26) that is formed on part of the electron supply layer (18) or part of the step layer (22) and contains acceptor impurities;

a gate electrode (28) formed on the gate layer (26); and

a source electrode (32) and a drain electrode (34) that are in contact with the electron supply layer (18), in which

the step layer (22) includes extension portions (22A and 22B) extending outside of the gate layer (26) in plan view, and

the extension portions (22A and 22B) each include an undoped layer.

(Supplement A2)

The nitride semiconductor apparatus (10) according to supplement A1, in which

the extension portions (22A and 22B) each extend outside of an entire outer periphery of the gate layer (26) in plan view.

(Supplement A3)

The nitride semiconductor apparatus (10) according to supplement A1 or A2, in which the acceptor impurities include at least one of Mg, Zn, and C.

(Supplement A4)

The nitride semiconductor apparatus (10) according to any one of supplements A1 to A3, further including:

a first passivation layer (24) formed on the extension portions (22A and 22B); and

a second passivation layer (30) covering the electron supply layer (18), the first passivation layer (24), and the gate electrode (28).

(Supplement A5)

The nitride semiconductor apparatus (500) according to any one of supplements A1 to A3, further including:

a first passivation layer (24) formed on the extension portions (22A and 22B);

a third passivation layer (502) formed to cover a top surface of the first passivation layer (24) and both side surfaces and part of a top surface of the gate layer (26); and

a second passivation layer (30) covering the electron supply layer (18), the third passivation layer (502), and the gate electrode (28).

(Supplement A6)

The nitride semiconductor apparatus (10) according to supplement A4 or A5, in which

the first passivation layer (24) is formed on the extension portions (22A and 22B) and is not formed on the top surface of the gate layer (26).

(Supplement A7)

The nitride semiconductor apparatus (10) according to any one of supplements A1 to A6, in which

the gate layer (26) is formed on the step layer (22).

(Supplement A8)

The nitride semiconductor apparatus (200) according to any one of supplements A1 to A7, in which

the step layer (202) further includes a base portion (202C) adjacent to the extension portions (202A and 202B),

a thickness of the base portion (202C) is smaller than a thickness of each of the extension portions (202A and 202B), and

the gate layer (204) is formed on the base portion (202C).

(Supplement A9)

The nitride semiconductor apparatus (100) according to any one of supplements A1 to A6, in which

the step layer (102) includes an opening portion (102C), and

the gate layer (104) is formed on the electron supply layer (18) in the opening portion (102C).

(Supplement A10)

The nitride semiconductor apparatus (600) according to any one of supplements A1 to A9, in which

the gate layer (602) includes
a top surface (602A) provided with the gate electrode (28),
a bottom surface (602B) on an opposite side of the top surface (602A), and
a side surface extending between the top surface (602A) and the bottom surface (602B),

a step (602C) recessed from the side surface is formed on an end portion of the bottom surface (602B), and

the nitride semiconductor apparatus (600) further includes

a mask portion (604) that is formed on the step (602C) and includes a nitride semiconductor with a composition different from those of the electron supply layer (18) and the step layer (22).

(Supplement A11)

The nitride semiconductor apparatus (600) according to supplement A10, in which

the mask portion (604) is formed from SiN.

(Supplement A12)

The nitride semiconductor apparatus (10) according to any one of supplements A1 to A11, in which

the electron transit layer (16) is formed from GaN,

the electron supply layer (18) is formed from AlₓGa₁₋ₓN,

the step layer (22) is formed from GaN, and

the gate layer (26) is formed from GaN containing the acceptor impurities, where

$$0.1 < x < 0.3 .$$

(Supplement A13)

The nitride semiconductor apparatus (600) according to supplement A10, in which

the electron transit layer (16) is formed from GaN,

the electron supply layer (18) is formed from AlₓGa₁₋ₓN,

the step layer (22) is formed from GaN, and

the gate layer (602) is formed from GaN containing the acceptor impurities, where

$$0.1 < x < 0.3 ,$$

and

the mask portion (604) is formed from Al_{y}Ga_{1*y}N, where

$$x \leq y \leq 1 .$$

(Supplement A14)

The nitride semiconductor apparatus (10) according to any one of supplements A1 to A13, in which

a thickness of the step layer (22) is equal to or smaller than 25 nm.

(Supplement A15)

The nitride semiconductor apparatus (10) according to any one of supplements A1 to A14, in which

a thickness of the step layer (22) is equal to or smaller than 15 nm.

(Supplement A16)

The nitride semiconductor apparatus (10) according to any one of supplements A1 to A15, in which

the extension portions (22A and 22B) include
a first extension portion (22A) extending outside of the gate layer (26) in plan view, toward a contact (18A) of the source electrode (32) and the electron supply layer (18), and
a second extension portion (22B) extending outside of the gate layer (26) in plan view, toward a contact (18B) of the drain electrode (34) and the electron supply layer (18), and

a width of the first extension portion (22A) is smaller than a width of the second extension portion (22B).

(Supplement A17)

The nitride semiconductor apparatus (10) according to supplement A16, in which

the width of the first extension portion (22A) is equal to or greater than 0.1 μm and equal to or smaller than 0.3 μm.

(Supplement A18)

The nitride semiconductor apparatus (10) according to supplement A16 or A17, in which

the width of the second extension portion (22B) is equal to or greater than 0.1 μm and equal to or smaller than 0.8 μm.

(Supplement A19)

The nitride semiconductor apparatus (10) according to any one of supplements A1 to A18, in which

the step layer (22) contains acceptor impurities at a concentration of equal to or smaller than 1×10¹⁸ cm⁻³.

(Supplement A20)

The nitride semiconductor apparatus (10) according to any one of supplements A1 to A19, in which

the gate layer (26) contains acceptor impurities at a concentration of equal to or greater than 1×10¹⁹ cm⁻³ and equal to or smaller than 3×10¹⁹ cm⁻³.

(Supplement A21)

The nitride semiconductor apparatus (400) according to any one of supplements A1 to A20, in which

the electron transit layer (402) includes a recess portion (402A), and the gate layer (406) is formed in a same region as the recess portion (402A) in plan view.

(Supplement A22)

The nitride semiconductor apparatus (400) according to any one of supplements A1 to A21, in which

the electron supply layer (404) includes
a first part (404A) formed in a same region as the gate layer (406) in plan view, and
a second part (404B) formed in a region different from the gate layer (406) in plan view, and
the first part (404A) is formed from AlGaN with a composition different from that of the second part (404B).

(Supplement A23)

The nitride semiconductor apparatus (400) according to any one of supplements A1 to A22, in which

the electron supply layer (404) includes
a first part (404A) formed in a same region as the gate layer (406) in plan view, and
a second part (404B) formed in a region different from the gate layer (406) in plan view, and
a thickness of the first part (404A) is different from a thickness of the second part (404B).

(Supplement B1)

A manufacturing method of a nitride semiconductor apparatus (10), the manufacturing method including:

forming a first nitride semiconductor layer (52);

forming, on the first nitride semiconductor layer (52), a second nitride semiconductor layer (54) with a band gap larger than a band gap of the first nitride semiconductor layer (52);

forming, on the second nitride semiconductor layer (54), a third nitride semiconductor layer (56) with a band gap smaller than the band gap of the second nitride semiconductor layer (54);

forming a first dielectric layer (58) on the third nitride semiconductor layer (56);

forming a first opening portion (58A) on the first dielectric layer (58);

forming a fourth nitride semiconductor layer (60) containing acceptor impurities, in a same region as the first opening portion (58A) in plan view, above the second nitride semiconductor layer (54);

forming a gate electrode (28) on the fourth nitride semiconductor layer (60);

selectively etching the third nitride semiconductor layer (56) such that the third nitride semiconductor layer (56) includes extension portions (22A and 22B) extending outside of the fourth nitride semiconductor layer (60) in plan view; and

forming a source electrode (32) and a drain electrode (34) that are in contact with the second nitride semiconductor layer (54).

(Supplement B2)

The manufacturing method of the nitride semiconductor apparatus (10) according to supplement B1, in which the forming the fourth nitride semiconductor layer (60) includes forming the fourth nitride semiconductor layer (60) on the third nitride semiconductor layer (56) exposed by the first opening portion (58A).

(Supplement B3)

The manufacturing method of the nitride semiconductor apparatus (100) according to supplement B1, in which

the forming the fourth nitride semiconductor layer (60) includes
forming a second opening portion (56A) communicating with the first opening portion (58A) on the third nitride semiconductor layer (56) to expose part of the second nitride semiconductor layer (54), and
forming the fourth nitride semiconductor layer (60) on the second nitride semiconductor layer (54) exposed by the second opening portion (56A).

(Supplement B4)

The manufacturing method of the nitride semiconductor apparatus (300) according to any one of supplements B1 to B3, further including:

removing the first dielectric layer (58).

(Supplement B5)

The manufacturing method of the nitride semiconductor apparatus (10) according to any one of supplements B1 to B4, in which

the third nitride semiconductor layer (56) is an undoped layer.

(Supplement B6)

The manufacturing method of the nitride semiconductor apparatus (10) according to any one of supplements B1 to B5, in which

the third nitride semiconductor layer (56) contains acceptor impurities at a concentration lower than that of the fourth nitride semiconductor layer (60).

(Supplement B7)

The manufacturing method of the nitride semiconductor apparatus (200) according to supplement B1, in which

the forming the fourth nitride semiconductor layer (60) includes
forming a recess portion (202A) communicating with the first opening portion (58A) on the third nitride semiconductor layer (56), and
forming the fourth nitride semiconductor layer (60) on the recess portion (202A).

(Supplement B8)

The manufacturing method of the nitride semiconductor apparatus (400) according to supplement B1, in which

the forming the fourth nitride semiconductor layer (60) includes
selectively etching through the third nitride semiconductor layer (56) and the second nitride semiconductor layer (54) to expose part of the first nitride semiconductor layer (52),
etching the exposed first nitride semiconductor layer (52) to form a recess portion (402A),
re-growing the second nitride semiconductor layer (54) on the recess portion (402A), and
forming the fourth nitride semiconductor layer (60) on the re-grown second nitride semiconductor layer (54).

(Supplement B9)

The manufacturing method of the nitride semiconductor apparatus (400) according to supplement B8, in which

the re-growing the second nitride semiconductor layer (54) includes
re-growing the second nitride semiconductor layer (54) by using growth conditions different from growth conditions used to form the second nitride semiconductor layer (54).

(Supplement B10)

The manufacturing method of the nitride semiconductor apparatus (400) according to supplement B8 or B9, in which

a depth of the recess portion (402A) is smaller than a thickness of the second nitride semiconductor layer (54).

The description above is just an example. Those skilled in the art can recognize that many more combinations and replacements can be made in addition to the constituent elements and the methods (manufacturing processes) listed for the purpose of describing the technique of the present disclosure. The present disclosure is intended to include all the substitutions, modifications, and changes included in the scope of the present disclosure including the claims.

What is claimed is:

1. A nitride semiconductor apparatus comprising:
an electron transit layer including a nitride semiconductor;
an electron supply layer that is formed on the electron transit layer and includes a nitride semiconductor with a band gap larger than a band gap of the electron transit layer;
a step layer that is formed on part of the electron supply layer and includes a nitride semiconductor with a band gap smaller than the band gap of the electron supply layer;
a gate layer that is formed on part of the electron supply layer or part of the step layer and contains acceptor impurities;
a gate electrode formed on the gate layer; and
a source electrode and a drain electrode that are in contact with the electron supply layer, wherein
the step layer includes extension portions extending outside of the gate layer in plan view, and
the extension portions each include an undoped layer.

2. The nitride semiconductor apparatus according to claim 1, wherein
the extension portions each extend outside of an entire outer periphery of the gate layer in plan view.

3. The nitride semiconductor apparatus according to claim 1, wherein
the acceptor impurities include at least one of Mg, Zn, and C.

4. The nitride semiconductor apparatus according to claim 1, further comprising:
a first passivation layer formed on the extension portions; and
a second passivation layer covering the electron supply layer, the first passivation layer, and the gate electrode.

5. The nitride semiconductor apparatus according to claim 4, wherein
the first passivation layer is formed on the extension portions and is not formed on a top surface of the gate layer.

6. The nitride semiconductor apparatus according to claim 1, wherein
the gate layer is formed on the step layer.

7. The nitride semiconductor apparatus according to claim 1, wherein
the step layer further includes a base portion adjacent to the extension portions,
a thickness of the base portion is smaller than a thickness of each of the extension portions, and
the gate layer is formed on the base portion.

8. The nitride semiconductor apparatus according to claim 1, wherein
the step layer includes an opening portion, and
the gate layer is formed on the electron supply layer in the opening portion.

9. The nitride semiconductor apparatus according to claim 1, wherein
the gate layer includes
a top surface provided with the gate electrode,
a bottom surface on an opposite side of the top surface, and
a side surface extending between the top surface and the bottom surface,
a step recessed from the side surface is formed on an end portion of the bottom surface, and
the nitride semiconductor apparatus further includes
a mask portion that is formed on the step and includes a nitride semiconductor with a composition different from those of the electron supply layer and the step layer.

10. The nitride semiconductor apparatus according to claim 9, wherein
the mask portion is formed from SiN.

11. The nitride semiconductor apparatus according to claim 1, wherein
the electron transit layer is formed from GaN,
the electron supply layer is formed from AlₓGa₁₋ₓN,
the step layer is formed from GaN, and
the gate layer is formed from GaN containing the acceptor impurities, where
$$0.1 < x < 0.3 .$$

12. The nitride semiconductor apparatus according to claim 9, wherein
the electron transit layer is formed from GaN,
the electron supply layer is formed from AlₓGa₁₋ₓN,
the step layer is formed from GaN, and
the gate layer is formed from GaN containing the acceptor impurities, where
$$0.1 < x < 0.3 ,$$
and
the mask portion is formed from Al_{y}Ga_{1-y}N, where
$$x \leq y \leq 1 .$$

13. The nitride semiconductor apparatus according to claim 1, wherein
a thickness of the step layer is equal to or smaller than 25 nm.

14. The nitride semiconductor apparatus according to claim 1, wherein
a thickness of the step layer is equal to or smaller than 15 nm.

15. The nitride semiconductor apparatus according to claim 1, wherein
the extension portions include
a first extension portion extending outside of the gate layer in plan view, toward a contact of the source electrode and the electron supply layer, and
a second extension portion extending outside of the gate layer in plan view, toward a contact of the drain electrode and the electron supply layer, and
a width of the first extension portion is smaller than a width of the second extension portion.

16. The nitride semiconductor apparatus according to claim 15, wherein
the width of the first extension portion is equal to or greater than 0.1 μm and equal to or smaller than 0.3 μm.

17. The nitride semiconductor apparatus according to claim 15, wherein
the width of the second extension portion is equal to or greater than 0.1 μm and equal to or smaller than 0.8 μm.

18. The nitride semiconductor apparatus according to claim 1, wherein
the step layer contains acceptor impurities at a concentration of equal to or smaller than 1×10¹⁸ cm⁻³.

19. The nitride semiconductor apparatus according to claim 1, wherein
the gate layer contains acceptor impurities at a concentration of equal to or greater than 1×10¹⁹ cm⁻³ and equal to or smaller than 3×10¹⁹ cm⁻³.

20. The nitride semiconductor apparatus according to claim 1, wherein
the electron transit layer includes a recess portion, and the gate layer is formed in a same region as the recess portion in plan view.
